(19) United States
(12) Patent Application Publication
(10) Pub. No.: US 2024/0324286 A1
(43) Pub. Date: Sep. 26, 2024

(54) DISPLAY APPARATUS

(71) Applicant: Samsung Display Co., Ltd., Yongin-si (KR)

(72) Inventors: Daehyun Kim, Yongin-si (KR); Sunghwan Kim, Yongin-si (KR); Heyjin Shin, Yongin-si (KR); Hwansoo Jang, Yongin-si (KR); Changkyu Jin, Yongin-si (KR); Wonkyu Kwak, Yongin-si (KR)

(21) Appl. No.: 18/437,105

(22) Filed: Feb. 8, 2024

(30) Foreign Application Priority Data
Mar. 24, 2023 (KR) 10-2023-0039086
Jul. 11, 2023 (KR) 10-2023-0090025

(51) Int. Cl. H10K 59/121; H01L 27/12; H10K 59/131

(52) U.S. Cl. CPC H10K 59/1213; H10K 59/131; H01L 27/1222

(57) ABSTRACT

A display apparatus including a display area and a peripheral area includes: a first thin-film transistor in the peripheral area, and including a silicon semiconductor layer; a second thin-film transistor in the display area, and including an oxide semiconductor layer over the silicon semiconductor layer; and a semiconductor pattern in the display area at the same layer as that of the silicon semiconductor layer of the first thin-film transistor.

### CROSS-REFERENCE TO RELATED APPLICATION

The present application claims priority to and the benefit of Korean Patent Application No. 10-2023-0039086, filed on Mar. 24, 2023, and Korean Patent Application No. 10-2023-0090025, filed on Jul. 11, 2023, in the Korean Intellectual Property Office, the entire disclosures of which are incorporated by reference herein.

### BACKGROUND

### 1. Field

Aspects of one or more embodiments of the present disclosure relate to a pixel, and a display apparatus including the pixel.

### 2. Description of Related Art

Recently, display apparatuses have been used for various purposes. Also, as the thicknesses and weights of the display apparatuses have decreased, the range of applications of the display apparatuses has increased.

As the display apparatuses are used in various ways, there may be various methods for designing the shapes of the display apparatuses, and functions linked to or associated with the display apparatuses have increased.

The above information disclosed in this Background section is for enhancement of understanding of the background of the present disclosure, and therefore, it may contain information that does not constitute prior art.

### SUMMARY

One or more embodiments of the present disclosure are directed to a display apparatus having improved display quality. However, the aspects and features of the present disclosure are not limited thereto.

The above and additional aspects and features will be set forth, in part, in the description that follows, and in part, will be apparent from the description, or may be learned by practicing one or more of the presented embodiments of the present disclosure.

According to one or more embodiments of the present disclosure, a display apparatus includes: a display area; a peripheral area; a first thin-film transistor in the peripheral area, and including a silicon semiconductor layer; a second thin-film transistor in the display area, and including an oxide semiconductor layer over the silicon semiconductor layer; and a semiconductor pattern in the display area at the same layer as that of the silicon semiconductor layer of the first thin-film transistor.

In an embodiment, the semiconductor pattern may include a silicon semiconductor.

In an embodiment, the semiconductor pattern may be configured to be in a floating state.

In an embodiment, the display apparatus may further include: a conductive layer overlapping with the semiconductor pattern; and signal lines electrically connected to opposite ends of the semiconductor pattern not overlapping with the conductive layer. The signal lines may be electrically connected to the conductive layer.

In an embodiment, the conductive layer may be at the same layer as that of a gate electrode of the first thin-film transistor.

In an embodiment, the oxide semiconductor layer of the second thin-film transistor may overlap with the semiconductor pattern.

In an embodiment, the display apparatus may further include: a plurality of conductive electrodes overlapping with the semiconductor pattern; and signal lines electrically connected to portions of the semiconductor pattern between adjacent conductive electrodes from among the plurality of conductive electrodes. The signal lines may be electrically connected to the plurality of conductive electrodes.

In an embodiment, the plurality of conductive electrodes may be at the same layer as that of a gate electrode of the first thin-film transistor.

In an embodiment, the oxide semiconductor layer of the second thin-film transistor may overlap with the semiconductor pattern.

In an embodiment, the display apparatus may further include: an upper conductive layer overlapping with the semiconductor pattern; a lower conductive layer overlapping with the semiconductor pattern; and signal lines electrically connected to opposite ends of the semiconductor pattern not overlapping with the upper conductive layer. The signal lines may be electrically connected to the upper conductive layer and the lower conductive layer.

In an embodiment, the upper conductive layer may be at the same layer as that of a gate electrode of the first thin-film transistor.

In an embodiment, the oxide semiconductor layer of the second thin-film transistor may overlap with the semiconductor pattern.

In an embodiment, the semiconductor pattern may include a plurality of semiconductor patterns spaced from each other in a row direction, and the display apparatus may further include: a conductive layer overlapping with the plurality of semiconductor patterns to cross the plurality of semiconductor patterns; a first signal line electrically connected to ends of the plurality of semiconductor patterns; and a second signal line electrically connected to other ends of the plurality of semiconductor patterns.

In an embodiment, the first signal line and the second signal line may be configured to be applied with a constant voltage signal, and the conductive layer may be configured to be applied with a signal including a voltage of a first voltage level and a voltage of a second voltage level lower than the first voltage level.

In an embodiment, the display apparatus may further include: a second semiconductor pattern at the same layer as that of the plurality of semiconductor patterns, and extending in the row direction; a second conductive layer overlapping with the second semiconductor pattern; and third signal lines electrically connected to opposite ends of the second semiconductor pattern not overlapping with the second conductive layer. The third signal lines may be configured to be applied with the same voltage as that supplied to the first signal line and the second signal line.

In an embodiment, the display apparatus may further include: a conductive layer overlapping with the semiconductor pattern; and a signal line electrically connected to the conductive layer.

In an embodiment, the semiconductor pattern may be electrically connected to a conductive line configured to supply a constant voltage.

In an embodiment, the display apparatus may further include a third thin-film transistor in the display area, and including an oxide semiconductor layer over the silicon semiconductor layer. The semiconductor pattern may be configured to electrically connect the oxide semiconductor layer of the second thin-film transistor to the oxide semiconductor layer of the third thin-film transistor.

According to one or more embodiments of the present disclosure, a display apparatus includes: a display area; a peripheral area; a semiconductor pattern in the display area; a conductive layer on the semiconductor pattern, and overlapping with the semiconductor pattern; a first electrode layer on the conductive layer, and overlapping with the conductive layer; an oxide semiconductor layer on the first electrode layer; a second electrode layer on the oxide semiconductor layer; and a third electrode layer on the second electrode layer, and overlapping with the second electrode layer.

In an embodiment, the semiconductor pattern may include a silicon semiconductor.

In an embodiment, the display apparatus may further include a lower conductive layer in the display area between a substrate and the semiconductor pattern, and the semiconductor pattern may overlap with the lower conductive layer.

In an embodiment, the display apparatus may further include: a silicon semiconductor layer in the peripheral area; and a fourth electrode layer on the silicon semiconductor layer, and overlapping with the silicon semiconductor layer. The silicon semiconductor layer may be at the same layer as that of the semiconductor pattern, and the fourth electrode layer may be at the same layer as that of the conductive layer.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIGS. 1A and 1B are plan views schematically illustrating a display apparatus, according to one or more embodiments;

FIG. 2 is a plan view schematically illustrating a display panel, according to an embodiment;

FIG. 3 is a cross-sectional view schematically illustrating the display panel taken along the line I-I′ of FIG. 2;

FIGS. 4A-8B are views schematically illustrating a semiconductor pattern of a display area, according to one or more embodiments;

FIG. 9 is an equivalent circuit diagram illustrating a pixel, according to an embodiment;

FIGS. 10-23 are views schematically illustrating elements according to layers of the pixel of FIG. 9;

FIG. 24 is a view schematically illustrating an arrangement of emission areas of a plurality of pixels, according to an embodiment;

FIG. 25 is a cross-sectional view taken along the line VIII-VIII′ of FIGS. 20 and 23;

FIG. 26 is a view schematically illustrating transistors and capacitors of the pixel of FIG. 9;

FIG. 27 is a view schematically illustrating conductive layers at an edge of a display area;

FIG. 28 is a cross-sectional view taken along the line X-X′ of FIG. 27;

FIG. 29 is a view schematically illustrating transistors and capacitors of the pixel of FIG. 9, according to an embodiment;

FIGS. 30-36 are views schematically illustrating elements according to layers of a pixel circuit of FIG. 29;

FIG. 37 is a layout view illustrating some elements of FIG. 29;

FIG. 38 is a cross-sectional view taken along the line XI-XI′ of FIG. 29;

FIG. 39 is a view schematically illustrating transistors and capacitors of the pixel of FIG. 9, according to an embodiment;

FIG. 40 is a cross-sectional view taken along the line XII-XII′ of FIG. 39;

FIG. 41 is a view schematically illustrating transistors and capacitors of the pixel of FIG. 9, according to an embodiment;

FIGS. 42 and 43 are views schematically illustrating some elements of a pixel circuit of FIG. 41;

FIG. 44 is a layout view illustrating some elements of FIG. 41;

FIG. 45 is a cross-sectional view taken along the line XIII-XIII′ of FIG. 41;

FIG. 46 is a view schematically illustrating transistors and capacitors of the pixel of FIG. 9, according to an embodiment; and

FIGS. 47 and 48 are views schematically illustrating some elements of a pixel circuit of FIG. 46.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

As used herein, the term “on” used in association with a device state may refer to a state in which a device is activated, and the term “off” may refer to a state in which a device is deactivated. The term “on” used in association with a signal received by a device may refer to a signal for activating a device, and the term “off” may refer to a signal for deactivating a device. A device may be activated by a high-level voltage or a low-level voltage. For example, a P-channel transistor (P-type transistor) is activated by a low-level voltage, and an N-channel transistor (N-type transistor) is activated by a high-level voltage. Accordingly, it should be understood that “on” voltages for the P-type transistor and the N-type transistor have opposite (e.g., high and low) voltage levels. Similarly, when an arbitrary signal is applied, it may mean that an on voltage (e.g., a high-level voltage) is applied, and when an arbitrary signal is not applied, it may mean that an off voltage (e.gh., a low-level voltage) is applied.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

According to one or more embodiments, a display apparatus may be implemented as an electronic device, such as a smartphone, a mobile phone, a smart watch, a navigation device, a game console, a television (TV), a vehicle head unit, a notebook computer, a laptop computer, a tablet computer, a personal media player (PMP), or a personal digital assistant (PDA). Also, the electronic device may be a flexible device.

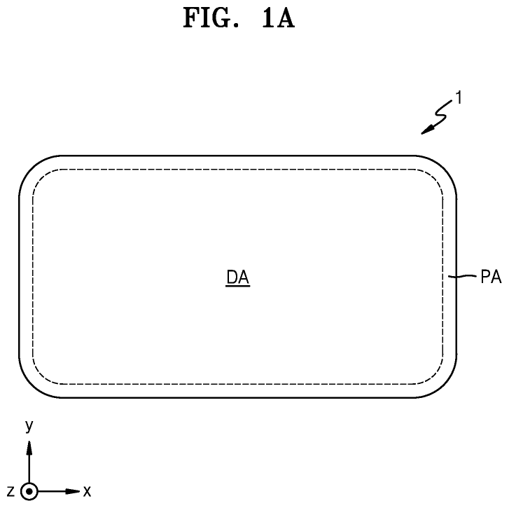

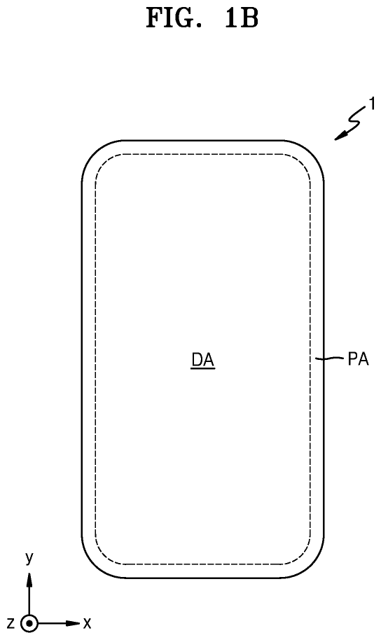

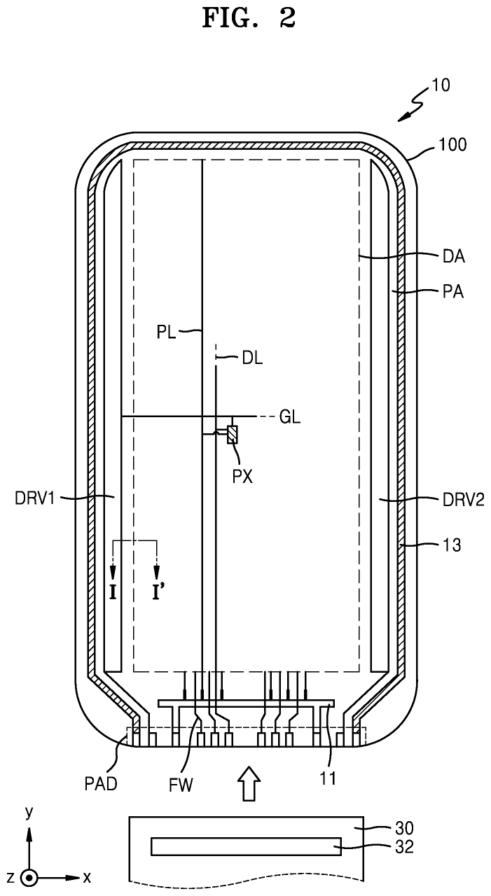

FIGS. 1A and 1B are plan views schematically illustrating a display apparatus, according to one or more embodiments. FIG. 2 is a plan view schematically illustrating a display panel, according to an embodiment.

Referring to FIGS. 1A and 1B, a display apparatus 1 may include a display area DA where an image is displayed, and a peripheral area PA outside the display area DA. The display area DA may be entirely surrounded (e.g., around a periphery thereof) by the peripheral area PA.

In a plan view, the display area DA may have a rectangular shape. In another embodiment, the display area DA may have a polygonal shape (e.g., a triangular shape, a pentagonal shape, a hexagonal shape, and/or the like), a circular shape, an elliptical shape, or an irregular shape. The display area DA may have a shape including round corners. In an embodiment, the display apparatus 1 may include the display area DA having a shape in which a length in the x-direction is greater than a length in the y-direction as shown in FIG. 1A. In another embodiment, the display apparatus 1 may include the display area DA having a shape in which a length in the y-direction is greater than a length in the x-direction as shown in FIG. 1B.

The display apparatus 1 may include a display panel 10, and a cover window to protect the display panel 10 may be located on the display panel 10.

Various elements constituting the display panel 10 may be located on a substrate 100. The substrate 100 may include the display area DA, and the peripheral area PA surrounding (e.g., around a periphery of) the display area DA.

A plurality of pixels PX may be located in the display area DA. A plurality of gate lines GL, a plurality of data lines DL, and the plurality of pixels PX connected to the gate lines GL and the data lines DL may be located in the display area DA. The plurality of pixels PX may be located in any of various suitable arrangements, such as a stripe arrangement, an RGBG arrangement (e.g., a PENTILE® arrangement, PENTILE® being a duly registered trademark of Samsung Display Co. Ltd.), a diamond arrangement, or a mosaic arrangement, and may display an image. Each pixel PX may include an organic light-emitting diode OLED as a display element (e.g., a light-emitting element), and the organic light-emitting diode OLED may be connected to a pixel circuit. The pixel circuit may include a plurality of transistors and at least one capacitor. Each pixel PX may emit light, for example, such as red light, green light, blue light, or white light, through the corresponding organic light-emitting diode OLED. Each pixel PX may be connected to a corresponding gate line from among the plurality of gate lines GL and a corresponding data line from among the plurality of data lines DL.

Each of the gate lines GL may extend in the x-direction (e.g., a row direction), and may be connected to the pixels PX located in the same row as each other. The gate line GL may transmit a gate signal to the pixels PX in the same row as each other. Each of the data lines DL may extend in the y-direction (e.g., a column direction), and may be connected to the pixels PX located in the same column as each other. The data line DL may transmit a data signal to each of the pixels PX in the same column as each other in synchronization with the gate signal. Each pixel PX may be connected to at least one from among a plurality of driving voltage lines PL to receive a driving voltage ELVDD. Each of the driving voltage lines PL may extend in the y-direction (e.g., the column direction), and may be connected to the pixels PX located in the same column as each other.

Although the pixel PX is illustrated as being connected to one gate line GL in FIG. 2, the present disclosure is not limited thereto. The pixel PX may be connected to one or more gate lines GL.

The pixel circuits for driving the pixels PX may be electrically connected to outer circuits located in the peripheral area PA. A first gate driving circuit DRV1, a second gate driving circuit DRV2, a terminal unit (e.g., a terminal area) PAD, a driving voltage supply line 11, and a common voltage supply line 13 may be located in the peripheral area PA.

In an embodiment, the peripheral area PA may be a non-display area where the pixels PX are not located. In another embodiment, a part of the peripheral area PA may be implemented as the display area DA. For example, a plurality of pixels PX may overlap with an outer circuit at at least one corner of the peripheral area PA. Accordingly, a dead area may be reduced, and the display area DA may be expanded.

The first gate driving circuit DRV1 may be connected to the plurality of gate lines GL, and may apply a gate signal to the pixel circuits for driving the pixels PX through the gate lines GL. A gate signal may be a gate control signal for controlling the turn on or turn off of a transistor having a gate connected to the gate line GL. The gate signal may be a square wave signal including a gate-on voltage for turning on the transistor and a gate-off voltage for turning off the transistor. The second gate driving circuit DRV2 may be located opposite to the first gate driving circuit DRV1 with respect to the display area DA, and may be parallel or substantially parallel to the first gate driving circuit DRV1. In an embodiment, some of the pixel circuits of the pixels PX of the display area DA may be electrically connected to the first gate driving circuit DRV1, and the others may be electrically connected to the second gate driving circuit DRV2. In another embodiment, the pixel circuits of the pixels PX of the display area DA may be electrically connected to the first gate driving circuit DRV1 and the second gate driving circuit DRV2. The second gate driving circuit DRV2 may be omitted as needed or desired.

The terminal unit PAD may be located on a side (e.g., at an end) of the substrate 100. The terminal unit PAD may be exposed without being covered by an insulating layer, and may be connected to a display circuit board 30. A display driver 32 may be located on the display circuit board 30.

The display driver 32 may generate a control signal that is transmitted to the first gate driving circuit DRV1 and the second gate driving circuit DRV2. The display driver 32 may include a data driving circuit. The data driving circuit may be connected to the plurality of data lines DL to generate a data signal, and the generated data signal may be transmitted to the pixel circuits of the pixels PX through a fan-out line FW and the data line DL connected to the fan-out line FW.

The display driver 32 may include a power supply circuit. The power supply circuit may supply the driving voltage ELVDD to the driving voltage supply line 11, and may supply a common voltage ELVSS to the common voltage supply line 13. The driving voltage ELVDD may be applied to the pixel circuits of the pixels PX through the driving voltage line PL connected to the driving voltage supply line 11, and the common voltage ELVSS may be applied to a counter electrode of a display element through the common voltage supply line 13.

The driving voltage supply line 11 may be connected to the terminal unit PAD, and may be located below the display area DA to extend in the x direction. The common voltage supply line 13 may be connected to the terminal unit PAD, and may have a loop shape with one side open to partially surround (e.g., around a periphery of) the display area DA.

Parts or all of the first gate driving circuit DRV1 and the second gate driving circuit DRV2 may be formed in (e.g., directly formed) in the peripheral area PA of the substrate 100 during a process of forming the pixel circuit in the display area DA of the substrate 100. The display driver 32 may be formed as an integrated circuit chip, and may be located on the display circuit board 30 electrically connected to the terminal unit PAD located on a side of the substrate 100. The display circuit board 30 may be a flexible printed circuit board (FPCB). In another embodiment, the display driver 32 may be directly located on the substrate by using a chip-on-glass (COG) or chip-on-plastic (COP) method.

In an embodiment, a plurality of transistors included in the pixel circuits of the display area DA may be N-type oxide thin-film transistors. A plurality of transistors included in an outer circuit of the peripheral area PA, for example, such as the first gate driving circuit DRV1 and the second gate driving circuit DRV2, may be P-type silicon thin-film transistors.

In the oxide thin-film transistor, a semiconductor layer may include an oxide. An oxide semiconductor may include a Zn oxide-based material, such as Zn oxide, In—Zn oxide, or Ga—In—Zn oxide. In some embodiments, the oxide semiconductor may be an In—Ga—Zn—O (IGZO) semiconductor containing a metal, such as indium (In) or gallium (Ga), in ZnO. In an embodiment, the oxide thin-film transistor may be a low-temperature polycrystalline oxide (LTPO) thin-film transistor. The silicon thin-film transistor may be a low-temperature polysilicon (LTPS) thin-film transistor in which a semiconductor layer includes amorphous silicon or polysilicon.

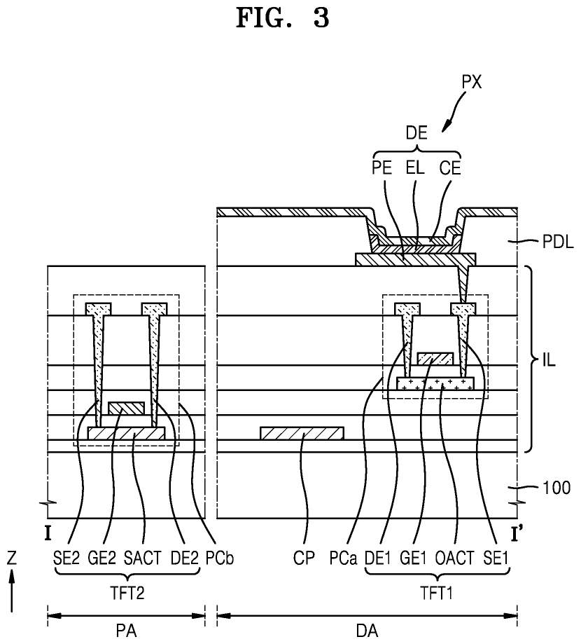

FIG. 3 is a cross-sectional view schematically illustrating the display panel taken along the line I-I′ of FIG. 2.

Referring to FIG. 3, the pixel PX may be located in the display area DA of the substrate 100, and a driving circuit PCb may be located in the peripheral area PA. The driving circuit PCb may be any one of the first gate driving circuit DRV1 and the second gate driving circuit DRV2 of FIG. 2.

The pixel PX may include a pixel circuit PCa, and a light-emitting element DE as a display element connected to the pixel circuit PCa. An insulating layer IL may be provided between the substrate 100 and the light-emitting element DE. The insulating layer IL may include one or more inorganic insulating layers and/or one or more organic insulating layers. The pixel circuit PCa may include at least one thin-film transistor TFT1. The thin-film transistor TFT1 may include a semiconductor layer including an oxide (hereinafter, referred to as an oxide semiconductor layer) OACT, a gate electrode GE1, a source electrode SE1, and a drain electrode DE1. The source electrode SE1 and the drain electrode DE1 may be electrically connected to a source region and a drain region, respectively, of the oxide semiconductor layer OACT. The gate electrode GE1 may overlap with a channel region of the oxide semiconductor layer OACT. One of the source electrode SE1 and the drain electrode DE1, for example, such as the source electrode SE1, may be electrically connected to a pixel electrode PE of the light-emitting element DE. The light-emitting element DE may include the pixel electrode PE, an emission layer EL, and a counter electrode CE.

The driving circuit PCb may include at least one thin-film transistor TFT2. The thin-film transistor TFT2 may include a semiconductor layer including silicon (hereinafter, a silicon semiconductor layer) SACT, a gate electrode GE2, a source electrode SE2, and a drain electrode DE2. The source electrode SE2 and the drain electrode DE2 may be electrically connected to a source region and a drain region, respectively, of the silicon semiconductor layer SACT. The gate electrode GE2 may overlap with a channel region of the silicon semiconductor layer SACT.

Because the oxide semiconductor layer OACT constituting the thin-film transistor TFT1 in the display area DA may be formed after the silicon semiconductor layer SACT constituting the thin-film transistor TFT2 in the peripheral area PA is formed, as shown in FIG. 3, the oxide semiconductor layer OACT may be formed over (e.g., in a layer above) the silicon semiconductor layer SACT. In this case, there may be a low-temperature polysilicon (LTPS) density difference between the peripheral area PA and the display area DA, thereby, resulting in a pattern critical dimension (CD) distribution.

According to an embodiment, because a semiconductor pattern CP is formed in the display area DA when the thin-film transistor TFT2 is formed in the peripheral area PA, the pattern CD distribution between the peripheral area PA and the display area DA may be minimized or reduced. In an embodiment, the semiconductor pattern CP may be located around (e.g., adjacent to) the pixel circuit PCa. The semiconductor pattern CP may include the same material as that of the silicon semiconductor layer SACT. For example, the semiconductor pattern CP may include a silicon semiconductor. The semiconductor pattern CP may be a LTPS pattern. The semiconductor pattern CP may be formed in the display area DA concurrently or at the same time as when the silicon semiconductor layer SACT of the thin-film transistor TFT2 is formed in the peripheral area PA. The semiconductor pattern CP may function as a part of an independent transistor separate from the pixel circuit PCa or a conductive line in the display area DA.

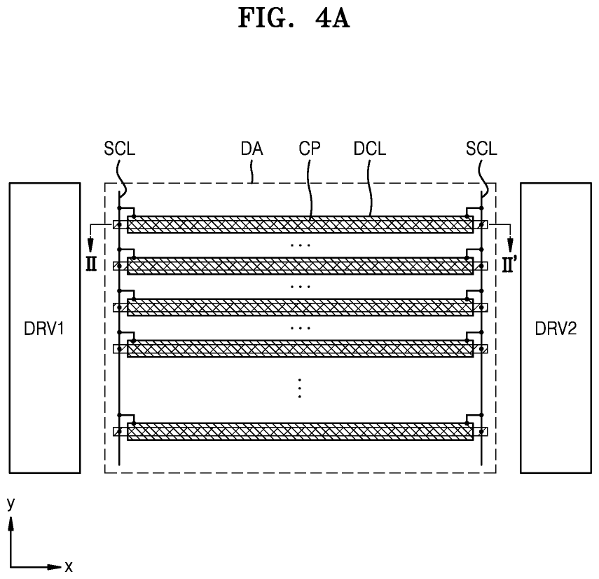

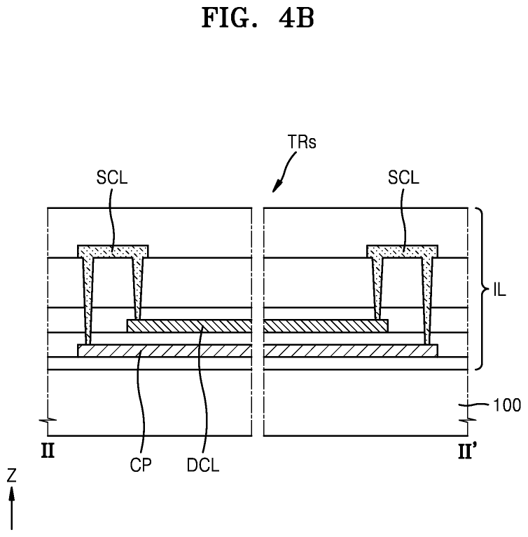

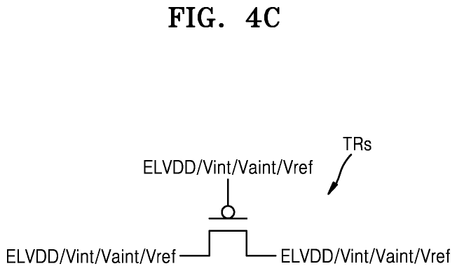

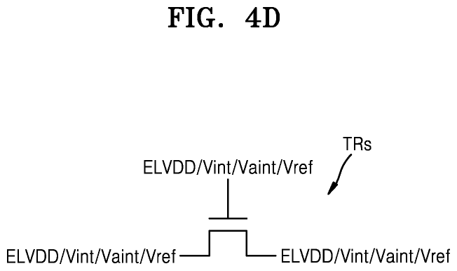

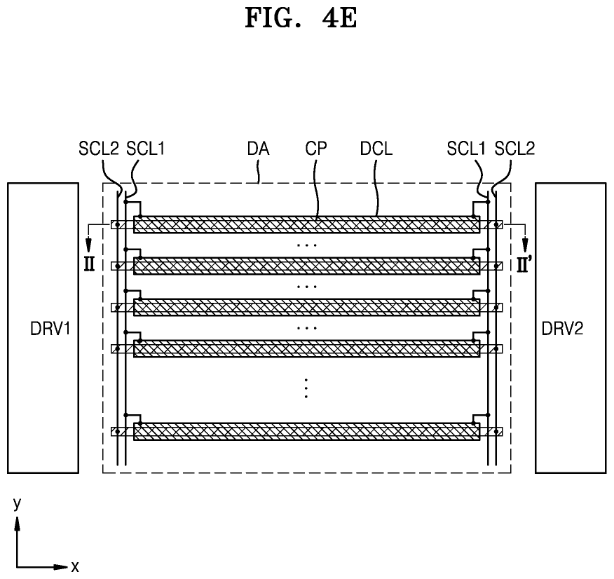

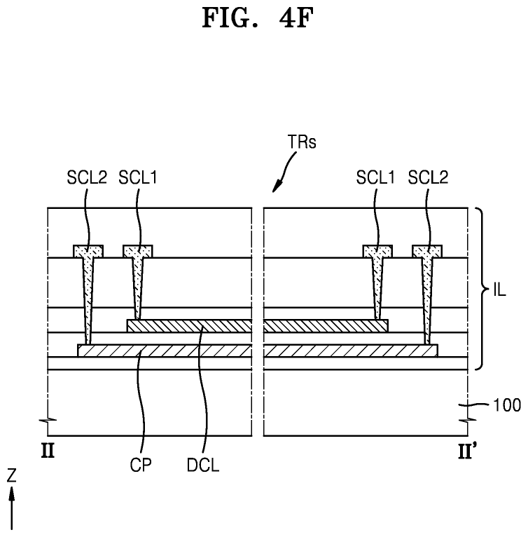

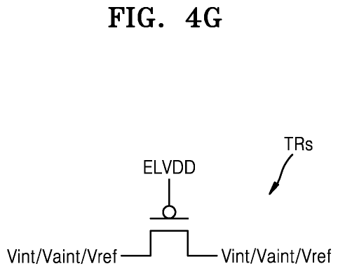

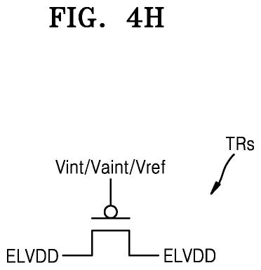

FIGS. 4A through 8B are views schematically illustrating a semiconductor pattern of a display area, according to one or more embodiments.

Referring to FIGS. 4A through 4D, in an embodiment, the semiconductor pattern CP may be an element of a transistor in the display area DA. For example, the semiconductor pattern CP may be a semiconductor layer of a silicon thin-film transistor TRs. The silicon thin-film transistor TRs may be an LTPS thin-film transistor.

The semiconductor pattern CP may extend in the x direction, and may be located in each row. A conductive layer DCL may extend in the x direction on the semiconductor pattern CP, and may be located in each row. In each row, the conductive layer DCL may be located over the semiconductor pattern CP to overlap with the semiconductor pattern CP. Both ends (e.g., opposite ends) of the semiconductor pattern CP at an edge of the display area DA may not be overlapped with the conductive layer DCL. The conductive layer DCL may include the same material as that of the gate electrode GE2 of the thin-film transistor TFT2. The conductive layer DCL may be formed in the display area DA concurrently or at the same time as when the gate electrode GE2 of the thin-film transistor TFT2 is formed in the peripheral area PA.

In each row, the semiconductor pattern CP and the conductive layer DCL may correspond to a silicon semiconductor layer and a gate electrode, respectively, of the silicon thin-film transistor TRs. Both ends (e.g., opposite ends) of the semiconductor pattern CP that are not overlapped with the conductive layer DCL may correspond to a source region (e.g., a source electrode) and a drain region (e.g., a drain electrode). A portion of the semiconductor pattern CP overlapped with the conductive layer DCL may correspond to a channel region between the source region and the drain region. A length of the channel region of the silicon thin-film transistor TRs and a length of a portion corresponding to the channel region of the semiconductor pattern CP may be or may substantially be a length of a row (e.g., a pixel line) of the display area DA.

The semiconductor pattern CP and the conductive layer DCL may be electrically connected to a signal line SCL. The signal line SCL may extend in the y direction. The signal line SCL may receive a DC voltage such as a driving voltage ELVDD, a first initialization voltage Vint, a second initialization voltage Vaint, or a reference voltage Vref. Accordingly, each of a gate electrode, a source region (e.g., a source electrode), and a drain region (e.g., a drain electrode) of the silicon thin-film transistor TRs may receive the driving voltage ELVDD, the first initialization voltage Vint, the second initialization voltage Vaint, or the reference voltage Vref.

In an embodiment, the silicon thin-film transistor TRs may be a P-type LTPS thin-film transistor as shown in FIG. 4C, or may be an N-type LTPS thin-film transistor as shown in FIG. 4D. FIGS. 4A through 4D show an example in which the same voltage is applied to the gate electrode, the source region (e.g., the source electrode), and the drain region (e.g., the drain electrode) of the silicon thin-film transistor TRs.

In another embodiment, a voltage applied to the gate electrode of the silicon thin-film transistor TRs and a voltage applied to the source region (e.g., the source electrode) and the drain region (e.g., the drain electrode) may be different from each other. For example, as shown in FIGS. 4E and 4F, the conductive layer DCL may be electrically connected to a first signal line SCL1, and the semiconductor pattern CP may be electrically connected to a second signal line SCL2. The first signal line SCL1 and the second signal line SCL2 may be located at (e.g., in or on) the same layer as each other as shown in FIG. 4F, or may be located at (e.g., in or on) different layers from each other. The first signal line SCL1 may receive the driving voltage ELVDD, and the second signal line SCL2 may receive a DC voltage different from the driving voltage ELVDD, for example, such as the first initialization voltage Vint, the second initialization voltage Vaint, or the reference voltage Vref. Accordingly, as shown in FIG. 4G, the gate electrode of the silicon thin-film transistor TRs may receive the driving voltage ELVDD, and the source region (e.g., the source electrode) and the drain region (e.g., the drain electrode) may receive the first initialization voltage Vint, the second initialization voltage Vaint, or the reference voltage Vref.

The silicon thin-film transistor TRs illustrated in FIGS. 4A through 4G may be a non-operating transistor that is not involved in the operation of the pixel PX or light emission of the pixel PX, and may be always in an off state so as to not operate.

In another embodiment, the silicon thin-film transistor TRs may be an operating transistor that is not involved in the operation of the pixel PX or light emission of the pixel PX, but may always operate (e.g., may always be) in an on state.

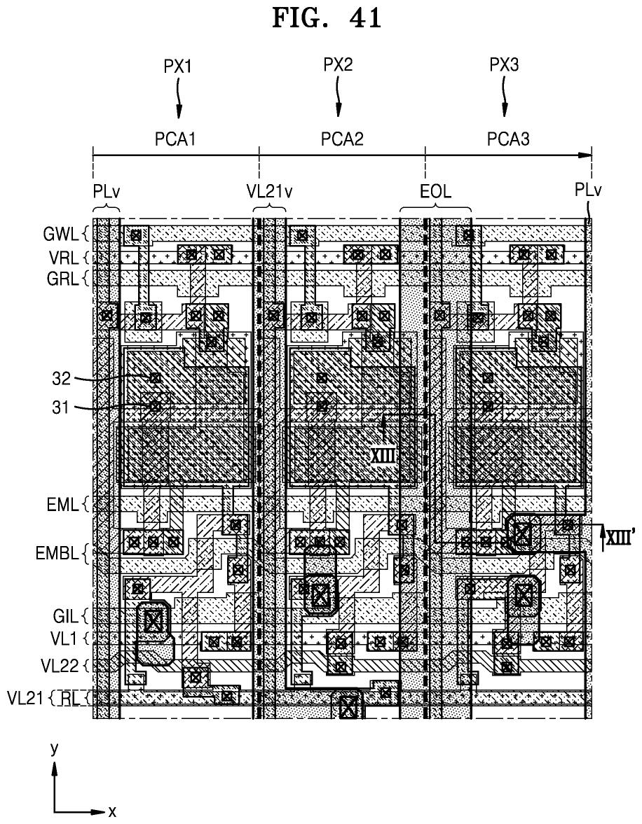

The silicon thin-film transistor TRs that is always in an on state may be implemented by applying a voltage, which may be higher than a voltage applied to a gate electrode, to a source region (e.g., a source electrode) and a drain region (e.g., a drain electrode) of a P-type LTPS thin-film transistor, and/or by applying a voltage, which is lower than a voltage applied to a gate electrode, to a source region (e.g., a source electrode) and a drain region (e.g., a drain electrode) of an N-type LTPS thin-film transistor. For example, as shown in FIGS. 4E and 4F, the conductive layer DCL may be electrically connected to the first signal line SCL1, and the semiconductor pattern CP may be electrically connected to the second signal line SCL2. As shown in FIG. 4H, in the silicon thin-film transistor TRs implemented as a P-type LTPS thin-film transistor, the gate electrode may receive the first initialization voltage Vint, the second initialization voltage Vaint, or the reference voltage Vref, and the source region (e.g., the source electrode) and the drain region (e.g., the drain electrode) may receive the driving voltage ELVDD. As another example, as shown in FIG. 41, in the silicon thin-film transistor TRs implemented as an N-type LTPS thin-film transistor, the gate electrode may receive the driving voltage ELVDD, and the source region (e.g., the source electrode) and the drain region (e.g., the drain electrode) may receive the first initialization voltage Vint, the second initialization voltage Vaint, or the reference voltage Vref.

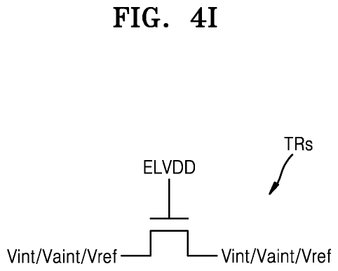

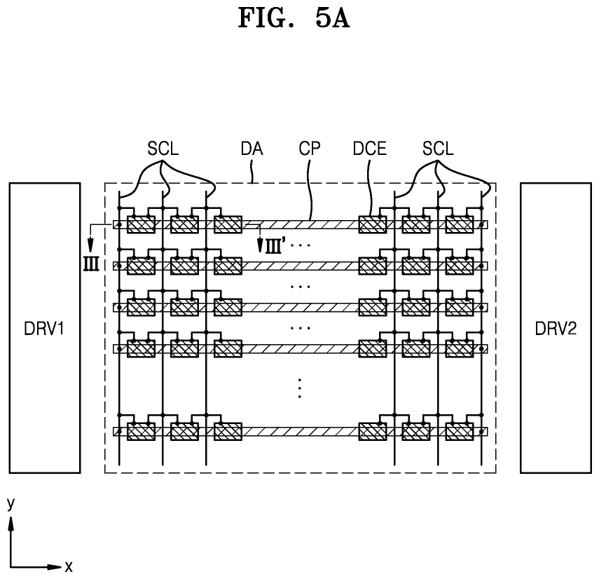

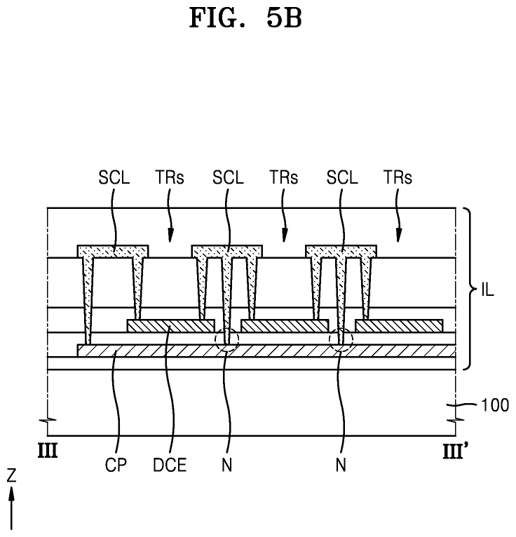

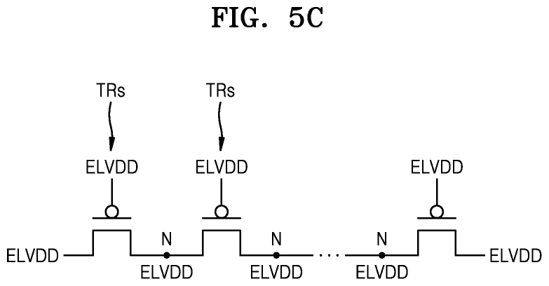

FIGS. 4A through 4I show an example in which one silicon thin-film transistor TRs is formed in each row. In another embodiment, as shown in FIGS. 5A through 5C, a plurality of silicon thin-film transistors TRs that are serially connected to each other may be formed in each row.

The semiconductor layer CP may extend in the x direction, and may be located in each row. A plurality of conductive electrodes DCE, each having an island shape, may be located over the semiconductor pattern CP in each row. In each row, the conductive electrodes DCE may be located over the semiconductor pattern CP to be spaced apart from each other in the x direction, and may overlap with the semiconductor pattern CP. The conductive electrodes DCE may include the same material as that of the gate electrode GE2 of the thin-film transistor TFT2. The conductive electrodes DCE may be formed in the display area DA concurrently or at the same time as when the gate electrode GE2 of the thin-film transistor TFT2 is formed in the peripheral area PA.

In each row, the semiconductor pattern CP and the conductive electrode DCE may correspond to a silicon semiconductor layer and a gate electrode, respectively, of the silicon thin-film transistor TRs. Portions of the semiconductor pattern CP not overlapped with the conductive electrode DCE may correspond to a source region (e.g., a source electrode) and a drain region (e.g., a drain electrode). A portion of the semiconductor pattern CP overlapped with the conductive electrode DCE may correspond to a channel region between the source region and the drain region. A length of the channel region of the silicon thin-film transistor TRs and a length of a portion corresponding to the channel region of the semiconductor pattern CP may be or may substantially be a length of the conductive electrode DCE in the x direction.

The semiconductor pattern CP and the conductive electrodes DCE may be electrically connected to the signal line SCL. The signal line SCL may extend in the y direction, and may receive the driving voltage ELVDD. Accordingly, each of a gate electrode, a source region (e.g., a source electrode), and a drain region (e.g., a drain electrode) of the silicon thin-film transistor TRs may receive the driving voltage ELVDD. An intermediate node N between adjacent silicon thin-film transistors TRs may be a portion of the semiconductor pattern CP not overlapped with the conductive electrode DCE between adjacent conductive electrodes DCE. In the intermediate node N, the signal line SCL may contact the semiconductor pattern CP, so that the signal line SCL and the semiconductor pattern CP are electrically connected to each other. As shown in FIG. 5B, each signal line SCL may be a source electrode or a drain electrode electrically connected to a gate electrode.

Similar to FIGS. 4C and 4D, each of the gate electrode, the source region (e.g., the source electrode), and the drain region (e.g., the drain electrode) of each of the silicon thin-film transistors TRs may receive the first initialization voltage Vint, the second initialization voltage Vaint, or the reference voltage Vref, in addition to the driving voltage ELVDD. The silicon thin-film transistors TRs may be P-type LTPS thin-film transistors, or N-type LTPS thin-film transistors.

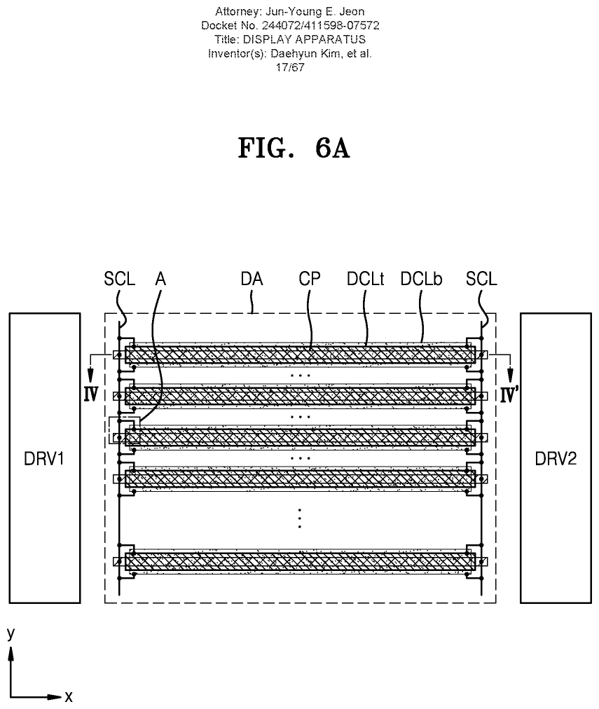

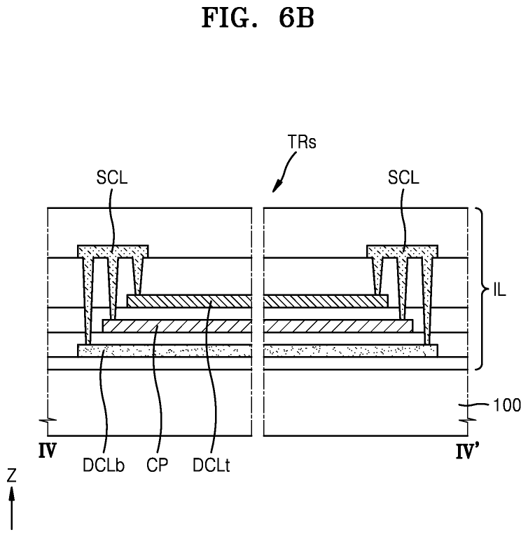

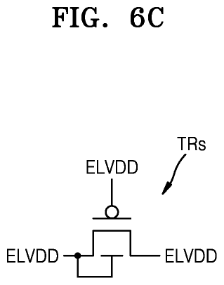

In an embodiment, as show in FIGS. 6A through 6C, the semiconductor pattern CP may be an element of a 4-terminal silicon thin-film transistor TRs in the display area DA. For example, the semiconductor pattern CP may be a semiconductor layer of the silicon thin-film transistor TRs.

The semiconductor pattern CP may extend in the x direction, and may be located in each row. An upper conductive layer DCLt may be located over the semiconductor pattern CP. The upper conductive layer DCLt may extend in the x direction, and may be located in each row. The upper conductive layer DCLt may overlap with the semiconductor pattern CP. A lower conductive layer DCLb may be located under the semiconductor pattern CP. The lower conductive layer DCLb may extend in the x direction, and may be located in each row. The semiconductor pattern CP may be located over the lower conductive layer DCLb to overlap with the lower conductive layer DCLb. Both ends (e.g., opposite ends) of the semiconductor pattern CP at an edge of the display area DA may not be overlapped with the upper conductive layer DCLt. The upper conductive layer DCLt may include the same material as that of the gate electrode GE2 of the thin-film transistor TFT2. The upper conductive layer DCLt may be formed in the display area DA concurrently or at the same time as when the gate electrode GE2 of the thin-film transistor TFT2 is formed in the peripheral area PA.

In each row, the semiconductor pattern CP, the upper conductive layer DCLt, and the lower conductive layer DCLb may correspond to a silicon semiconductor layer, a top gate electrode, and a bottom gate electrode, respectively, of the 4-terminal silicon thin-film transistor TRs. Both ends (e.g., opposite ends) of the semiconductor pattern CP not overlapped with the upper conductive layer DCLt may correspond to a source region (e.g., a source electrode) and a drain region (e.g., a drain electrode). A portion of the semiconductor pattern CP overlapped with the upper conductive layer DCLt may correspond to a channel region between the source region and the drain region. A length of the channel region of the 4-terminal silicon thin-film transistor TRs and a length of a portion corresponding to the channel region of the semiconductor pattern CP may be or may substantially be a length of a row of the display area DA.

The semiconductor pattern CP, the upper conductive layer DCLt, and the lower conductive layer DCLb may be electrically connected to the signal line SCL. The signal line SCL may extend in the y direction, and may receive the driving voltage ELVDD. Accordingly, each of a gate electrode, a source region (e.g., a source electrode), and a drain region (e.g., a drain electrode) of the silicon thin-film transistor TRs may receive the driving voltage ELVDD.

FIGS. 6A through 6C show an example in which one 4-terminal silicon thin-film transistor TRs is formed in each row. In another embodiment, similar to FIG. 5A, a plurality of upper conductive layers DCLt, each having an island shape, may be spaced apart from each other in the x direction to overlap with the semiconductor pattern CP, so that a plurality of 4-terminal silicon thin-film transistors TRs that are serially connected to each other are formed.

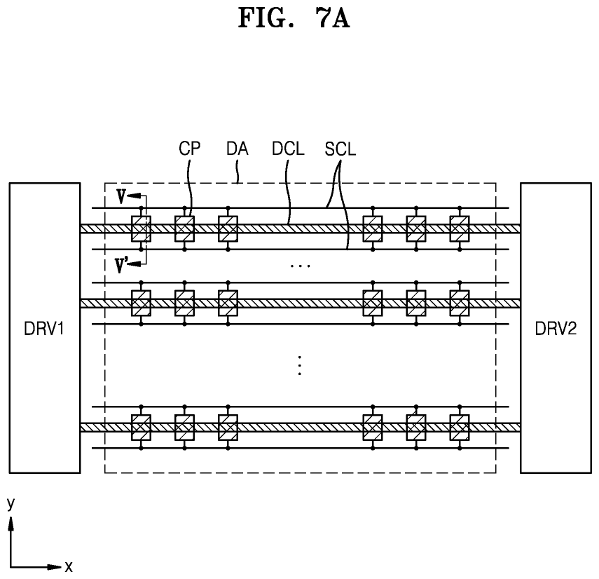

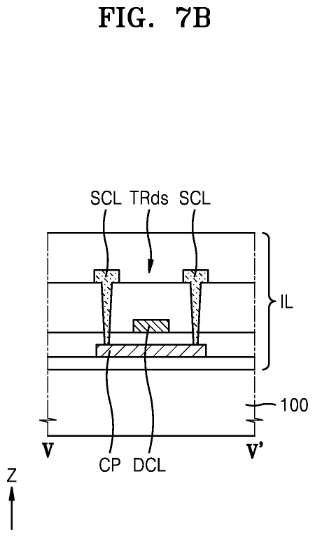

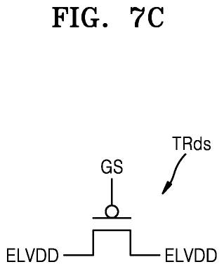

Referring to FIGS. 7A through 7C, in an embodiment, the semiconductor pattern CP may be an element of a silicon thin-film transistor TRds in the display area DA. For example, the semiconductor pattern CP may be a semiconductor layer of the silicon thin-film transistor TRds. The silicon thin-film transistor TRds may be an operating transistor that is not involved in the operation of the pixel PX or light emission of the pixel PX, but operates according to a signal applied to a gate electrode. The silicon thin-film transistor TRds may be an LTPS thin-film transistor.

A plurality of semiconductor patterns CP may be located in each row. In each row, the plurality of semiconductor patterns CP may be spaced apart from each other in the x direction. The conductive layer DCL may extend in the x direction, and may be located in each row. In each row, the conductive layer DCL may be located over the plurality of semiconductor patterns CP, may cross the semiconductor patterns CP, and may partially overlap with the semiconductor patterns CP. The conductive layer DCL may include the same material as that of the gate electrode GE2 of the thin-film transistor TFT2. The conductive layer DCL may be formed in the display area DA concurrently or at the same time as when the gate electrode GE2 of the thin-film transistor TFT2 is formed in the peripheral area PA.

Both ends (e.g., opposite ends) of the semiconductor pattern CP may be electrically connected to the signal line SCL to receive the driving voltage ELVDD. Both ends (e.g., opposite ends) of the conductive layer DCL may be connected to the first gate driving circuit DRV1 and/or the second gate driving circuit DRV2. The conductive layer DCL may receive a gate signal GS from the first gate driving circuit DRV1 and/or the second gate driving circuit DRV2.

The semiconductor pattern CP and a portion of the conductive layer DCL overlapping with the semiconductor pattern CP may correspond to a silicon semiconductor layer and a gate electrode, respectively, of the silicon thin-film transistor TRds. A plurality of silicon thin-film transistors TRds that are connected to each other in parallel may be provided in each row. Both ends (e.g., opposite ends) of the semiconductor pattern CP not overlapped with the conductive layer DCL may correspond to a source region (e.g., a source electrode) and a drain region (e.g., a drain electrode). A portion of the semiconductor pattern CP overlapped with the conductive layer DCL may correspond to a channel region between the source region and the drain region. A length of the channel region of the silicon thin-film transistor TRs and a length of a portion corresponding to the channel region of the semiconductor pattern CP may be or may substantially be a width of the conductive layer DCL in the y direction.

The semiconductor pattern CP may receive the driving voltage ELVDD from the signal line SCL, and the conductive layer DCL may receive the gate signal GS from the first gate driving circuit DRV1 and/or the second gate driving circuit DRV2, so that the silicon thin-film transistor TRds operates in response to the gate signal GS.

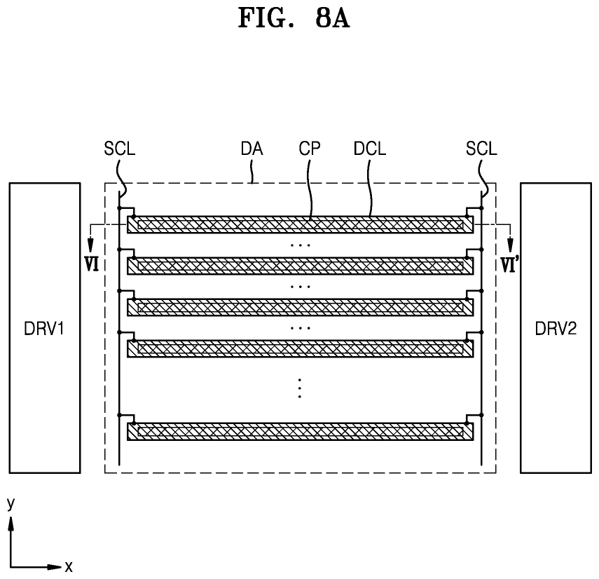

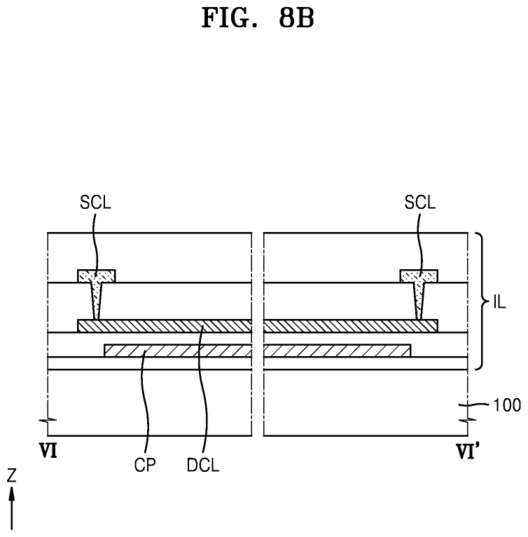

Referring to FIGS. 8A and 8B, in an embodiment, the semiconductor pattern CP in a floating state may be located in the display area DA, and the conductive layer DCL to which a constant voltage (e.g., a certain or predetermined constant voltage) is supplied may be located over the semiconductor pattern CP to overlap with the semiconductor pattern CP. The semiconductor pattern CP may extend in the x direction and may be located in each row. The conductive layer DCL may extend in the x direction and may be located in each row. The conductive layer DCL may be electrically connected to the signal line SCL. The signal line SCL may extend in the y direction, and may receive the driving voltage ELVDD. In another embodiment, the conductive layer DCL illustrated in FIGS. 8A and 8B may be omitted, and only the semiconductor pattern CP in a floating state may extend in the x direction and may be located in each row.

In another embodiment, the semiconductor pattern CP may be designed in the display area DA to function as a connection line that connects elements constituting the pixel circuit PCa in the display area DA to each other, or as a constant voltage line that supplies a voltage (e.g., a certain or predetermined voltage) to the pixel circuit PCa.

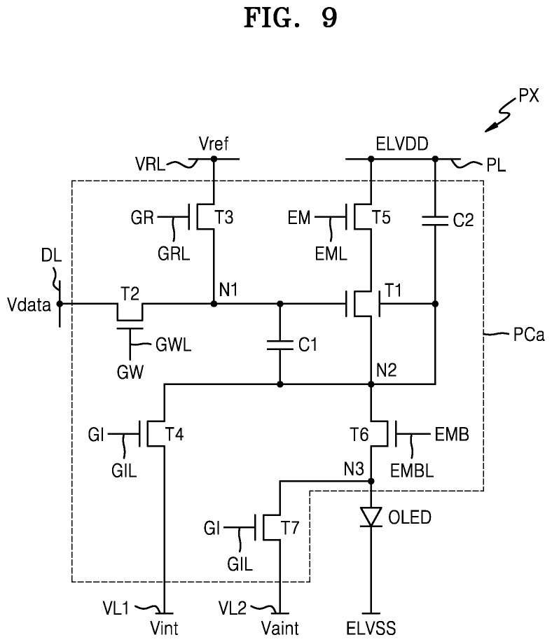

FIG. 9 is an equivalent circuit diagram illustrating a pixel, according to an embodiment.

Referring to FIG. 9, the pixel PX may include an organic light-emitting diode OLED as a display element, and the pixel circuit PCa connected to the organic light-emitting diode OLED.

The pixel PX may be connected to a first gate line GWL that transmits a first gate signal GW, a second gate signal GIL that transmits a second gate signal GI, a third gate line GRL that transmits a third gate signal GR, a fourth gate line EML that transmits a fourth gate signal EM, a fifth gate line EMBL that transmits a fifth gate signal EMB, and a data line DL that transmits a data signal Vdata. Because light emission of the pixel PX is controlled by the fourth gate signal EM and the fifth gate signal EMB, the fourth gate signal EM and the fifth gate signal EMB may be referred to as emission control signals, and the fourth gate line EML and the fifth gate line EMBL may be referred to as emission control lines.

The pixel PX may be connected to a driving voltage line PL that transmits a driving voltage ELVDD, a reference voltage line VRL that transmits a reference voltage Vref, a first initialization voltage line VL1 that transmits a first initialization voltage Vint, and a second initialization voltage line VL2 that transmits a second initialization voltage Vaint.

A voltage level of the driving voltage ELVDD may be higher than a voltage level of the common voltage ELVSS. A voltage level of the reference voltage Vref may be lower than a voltage level of the driving voltage ELVDD. A voltage level of the first initialization voltage Vint may be lower than a voltage level of the common voltage ELVSS. A voltage level of the second initialization voltage Vaint may be higher than a voltage level of the first initialization voltage Vint. A voltage level of the second initialization voltage Vaint may be equal to or higher than a voltage level of the common voltage ELVSS.

The pixel circuit PCa may include first to seventh transistors T1 to T7, and first and second capacitors C1 and C2. The first to seventh transistors T1 to T7 may be N-type thin-film transistors. The first transistor T1 may be a driving transistor that outputs a driving current corresponding to a data signal. The second to seventh transistors T2 to T7 may be switching transistors that transmit signals. A first terminal (e.g., a first electrode) and a second terminal (e.g., a second electrode) of each of the first to seventh transistors T1 to T7 may be a source or a drain according to voltages of the first terminal and the second terminal. For example, according to voltages of the first terminal and the second terminal, the first terminal may be a drain and the second terminal may be a source, or the first terminal may be a source and the second terminal may be a drain.

A node to which a first gate of the first transistor T1 is connected may be defined as a first node N1. A node to which the second terminal of the first transistor T1 is connected may be defined as a second node N2.

The first transistor T1 may be connected between the driving voltage line PL and the organic light-emitting diode OLED. The first transistor T1 may be connected between the fifth transistor T5 and the sixth transistor T6. The first transistor T1 may include a gate, the first terminal, and the second terminal, the second terminal being connected to the second node N2. The gate of the first transistor T1 may include the first gate connected to the first node N1, and a second gate connected to the second node N2. The first gate and the second gate may be located at (e.g., in or on) different layers from each other to face each other. For example, the first gate and the second gate of the first transistor T1 may face each other with a semiconductor layer therebetween.

The first gate of the first transistor T1 may be connected to the second terminal of the second transistor T2, the first terminal of the third transistor T3, and the first capacitor C1. The second gate of the first transistor T1 may be connected to the first terminal of the sixth transistor T6, the first capacitor C1, and the second capacitor C2. The first terminal of the first transistor T1 may be connected to the driving voltage line PL via the fifth transistor T5, and the second terminal may be connected to the pixel electrode of the organic light-emitting diode OLED via the sixth transistor T6. The second terminal of the first transistor T1 may be connected to the first terminal of the fourth transistor T4, the first terminal of the sixth transistor T6, the first capacitor C1, and the second capacitor C2. The first transistor T1 may receive the data signal Vdata according to a switching operation of the second transistor T2, and may control the amount of driving current flowing to the organic light-emitting diode OLED.

The second transistor T2 (e.g., a write transistor) may be connected to the data line DL and the first gate of the first transistor T1. The second transistor T2 may include a gate connected to the first gate line GWL, the first terminal connected to the data line DL, and the second terminal connected to the first node N1. The second terminal of the second transistor T2 may be connected to the first gate of the first transistor T1, the first terminal of the third transistor T3, and the first capacitor C1. The second transistor T2 may be turned on by the first gate signal GW transmitted through the first gate line GWL to electrically connect the data line DL to the first node N1, and transmit the data signal Vdata transmitted through the data line DL to the first node N1.

The third transistor T3 (e.g., a first initialization transistor) may be connected to the first gate of the first transistor T1 and the reference voltage line VRL. The third transistor T3 may include a gate connected to the third gate line GRL, the first terminal connected to the first node N1, and the second terminal connected to the reference voltage line VRL. The first terminal of the third transistor T3 may be connected to the first gate of the first transistor T1, the second terminal of the second transistor T2, and the first capacitor C1. The third transistor T3 may be turned on by the third gate signal GR transmitted through the third gate line GRL to transmit the reference voltage Vref transmitted through the reference voltage line VRL to the first node N1.

The fourth transistor T4 (e.g., a second initialization transistor) may be connected to the first transistor T1 and the first initialization voltage line VL1. The fourth transistor T4 may include a gate connected to the second gate line GIL, the first terminal connected to the second node N2, and the second terminal connected to the first initialization voltage line VL1. The first terminal of the fourth transistor T4 may be connected to the second terminal of the first transistor T1, the first terminal of the sixth transistor T1, the first capacitor C1, and the second capacitor C2. The fourth transistor T4 may be turned on by the second gate signal GI transmitted through the second gate line GIL to transmit the first initialization voltage Vint transmitted through the first initialization voltage line VL1 to the second node N2.

The fifth transistor T5 (e.g., a first emission control transistor) may be connected to the driving voltage line PL and the first transistor T1. The fifth transistor T5 may include a gate connected to the fourth gate line EML, the first terminal connected to the driving voltage line PL, and the second terminal connected to the first terminal of the first transistor T1. The fifth transistor T5 may be turned on or turned off according to the fourth gate signal EM transmitted through the fourth gate line EML.

The sixth transistor T6 (e.g., a second emission control transistor) may be connected to the first transistor T1 and the organic light-emitting diode OLED. The sixth transistor T6 may be connected between the second node N2 and a third node N3. The sixth transistor T6 may include a gate connected to the fifth gate line EMBL, the first terminal connected to the second node N2, and the second terminal connected to the third node N3. The first terminal of the sixth transistor T6 may be connected to the second terminal of the first transistor T1, the first terminal of the fourth transistor T4, the first capacitor C1, and the second capacitor C2. The second terminal of the sixth transistor T6 may be connected to the first terminal of the seventh transistor T7 and the pixel electrode of the organic light-emitting diode OLED. The sixth transistor T6 may be turned on or turned off according to the fifth gate signal EMB transmitted through the fifth gate line EMBL.

The seventh transistor T7 (e.g., a third initialization transistor or reset transistor) may be connected between the organic light-emitting diode OLED and the second initialization voltage line VL2. The seventh transistor T7 may be connected between the sixth transistor T6 and the second initialization voltage line VL2. The seventh transistor T7 may include a gate connected to the second gate line GIL, the first terminal connected to the third node N3, and the second terminal connected to the second initialization voltage line VL2. The first terminal of the seventh transistor T7 may be connected to the second terminal of the sixth transistor T6 and the pixel electrode of the organic light-emitting diode OLED. The seventh transistor T7 may be turned by the second gate signal GI transmitted through the second gate line GIL to transmit the second initialization voltage Vaint transmitted through the second initialization voltage line VL2 to the third node N3.

The first capacitor C1 may be connected between the first gate of the first transistor T1 and the second terminal of the first transistor T1. A first electrode of the first capacitor C1 may be connected to the first node N1, and a second electrode may be connected to the second node N2. The first electrode of the first capacitor C1 may be connected to the first gate of the first transistor T1, the second terminal of the second transistor T2, and the first terminal of the third transistor T3. The second electrode of the first capacitor C1 may be connected to the second terminal and the second gate of the first transistor T1, the second electrode of the second capacitor C2, the first terminal of the fourth transistor T4, and the first terminal of the sixth transistor T6. The first capacitor C1 may be a storage capacitor to store a voltage corresponding to the data signal Vdata and a threshold voltage of the first transistor T1.

The second capacitor C2 may be connected between the driving voltage line PL and the second node N2. A first electrode of the second capacitor C2 may be connected to the driving voltage line PL. The second electrode of the second capacitor C2 may be connected to the second terminal and the second gate of the first transistor T1, the second electrode of the first capacitor C1, the first terminal of the fourth transistor T4, and the first terminal of the sixth transistor T6. A capacitance of the first capacitor C1 may be greater than a capacitance of the second capacitor C2.

The organic light-emitting diode OLED may be connected to the first transistor T1 through the sixth transistor T6. The organic light-emitting diode OLED may include the pixel electrode (e.g., an anode) connected to the third node N3 and a counter electrode (e.g., a cathode) facing the pixel electrode. The counter electrode may receive the common voltage ELVSS. The counter electrode may be a common electrode that is common to the plurality of pixels PX.

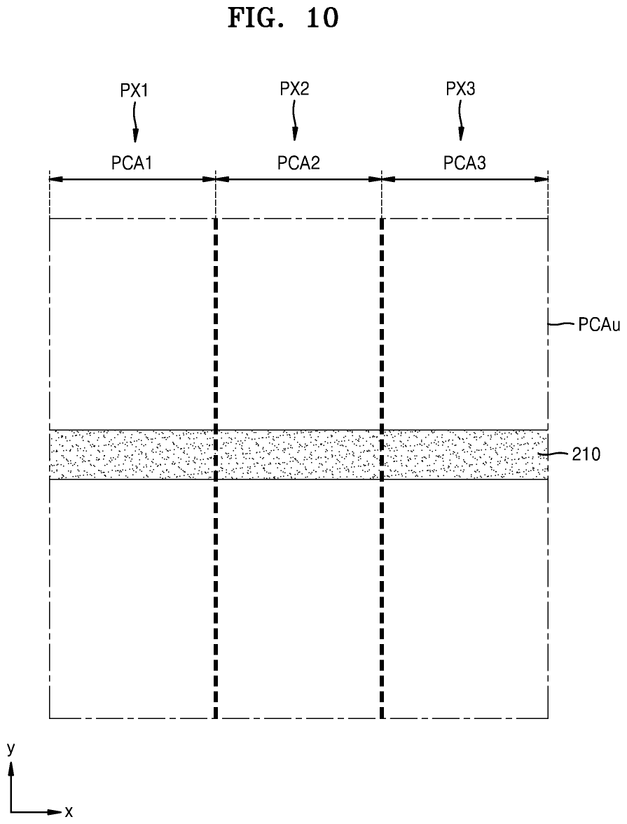

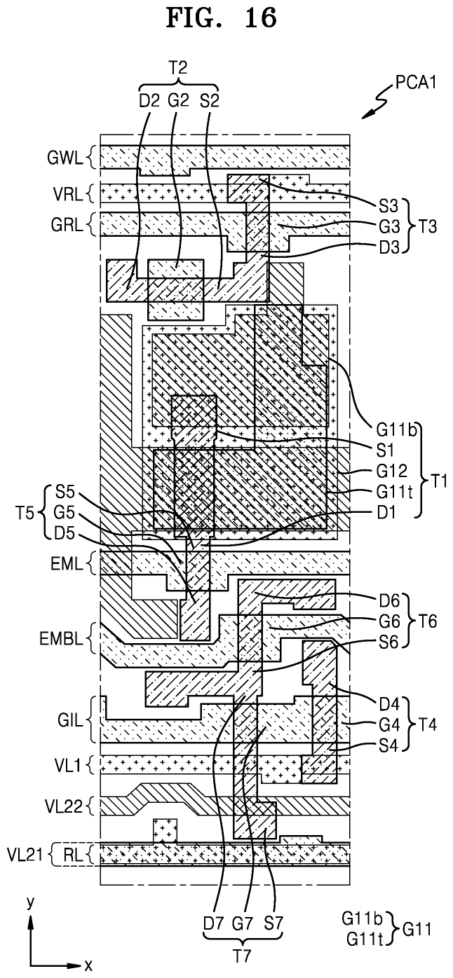

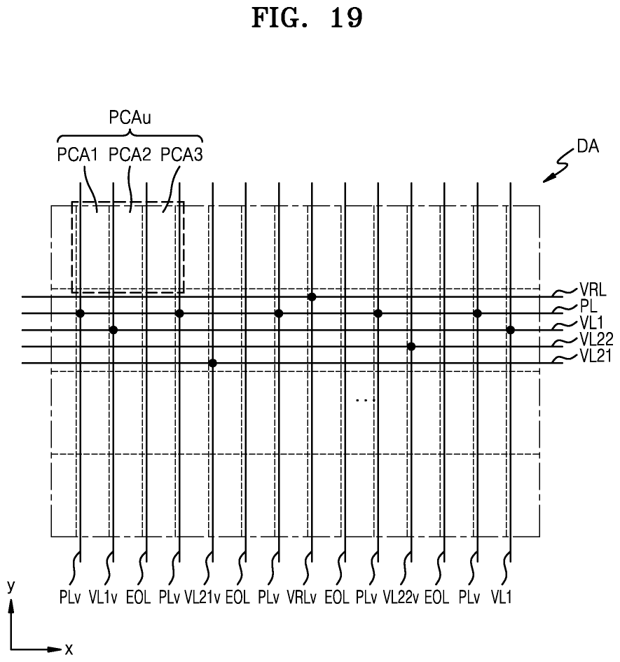

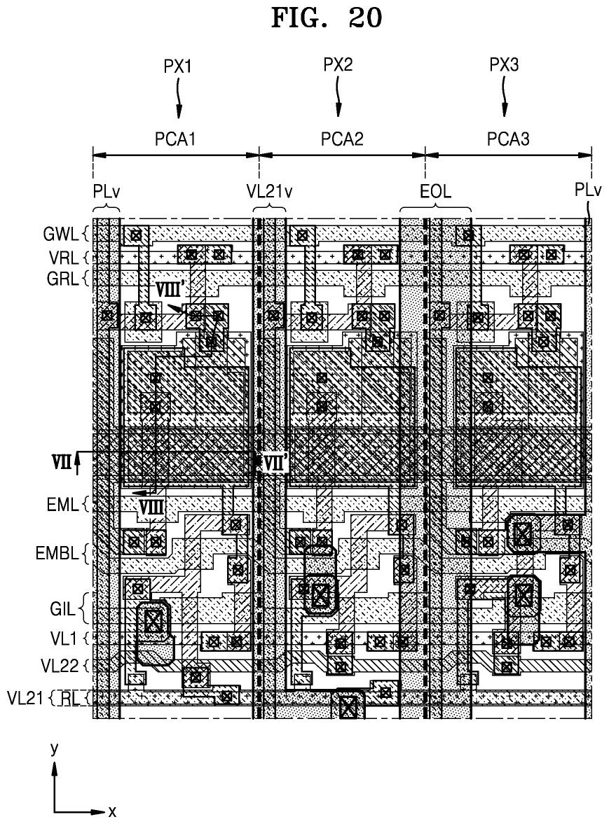

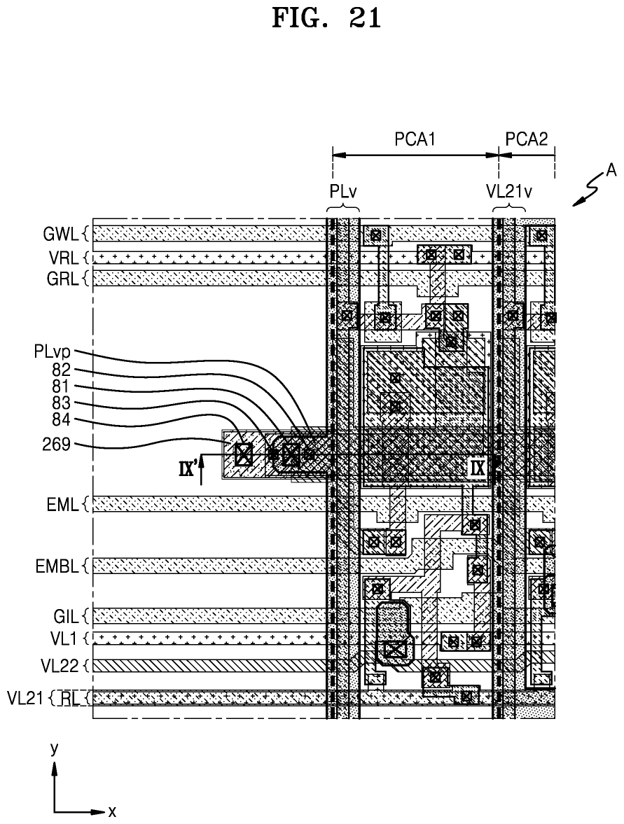

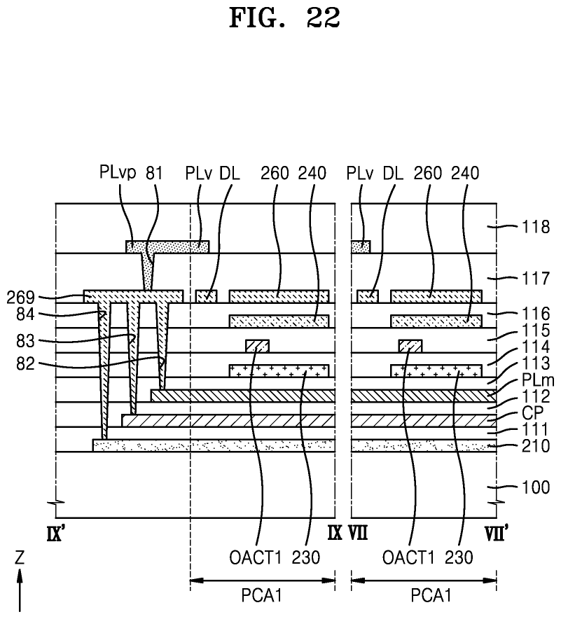

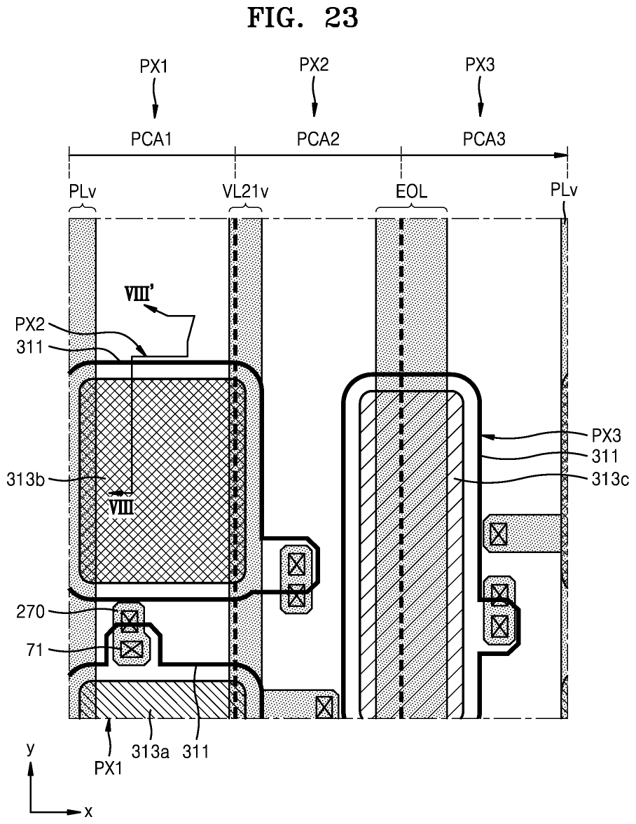

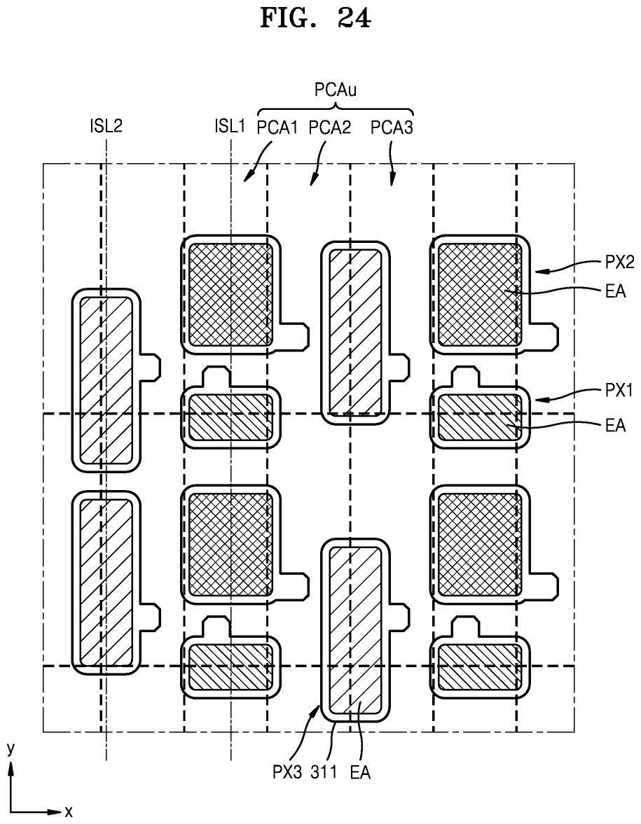

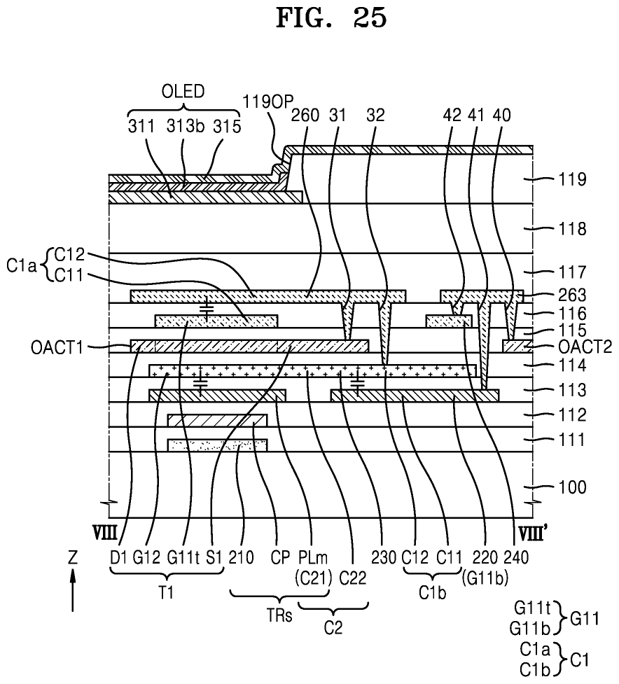

FIGS. 10 through 23 are views schematically illustrating elements according to layers of the pixel of FIG. 9. FIG. 16 is a view illustrating elements of a first circuit area PCA1. FIG. 21 is a view schematically illustrating conductive layers at an edge of a display area, according to an embodiment. FIG. 22 is a cross-sectional view taken along the line VII-VII′ of FIG. 20 and the line IX-IX′ of FIG. 21. FIG. 24 is a view schematically illustrating an arrangement of emission areas of a plurality of pixels, according to an embodiment. FIG. 25 is a cross-sectional view taken along the line VIII-VIII′ of FIGS. 20 and 23.

The plurality of pixels PX located in the display area DA may include a first pixel PX1 for emitting light of a first color, a second pixel PX2 for emitting light of a second color, and a third pixel PX3 for emitting light of a third color. For example, the first pixel PX1 may be a red pixel, the second pixel PX2 may be a green pixel, and the third pixel PX3 may be a blue pixel. The first pixel PX1, the second pixel PX2, and the third pixel PX3 may be repeatedly arranged according to a suitable pattern (e.g., a certain or predetermined pattern) along the x-direction and the y-direction. Each of the first pixel PX1, the second pixel PX2, and the third pixel PX3 may include a corresponding pixel circuit PC, and a corresponding organic light-emitting diode OLED as the display element electrically connected to the pixel circuit PC.

The display area DA defined on the substrate 100 may include a plurality of circuit areas where the pixel circuits are located, and where rows and columns cross each other. In an embodiment, a unit circuit area including two or more circuit areas that are adjacent to each other in the x direction may be defined. For example, a unit circuit area PCAu may include three circuit areas, such as a first circuit area PCA1, a second circuit area PCA2, and a third circuit area PCA3, which are adjacent to each other in the x direction. The first circuit area PCA1 may be an area where the pixel circuit PCa of the first pixel PX1 is located. The second circuit area PCA2 may be an area where the pixel circuit PCa of the second pixel PX2 is located. The third circuit area PCA3 may be an area where the pixel circuit PCa of the third pixel PX3 is located.

The pixel circuits PCa located in the first circuit area PCA1, the second circuit area PCA2, and the third circuit area PCA3 may be electrically connected to the display elements for emitting light of different colors from each other. The pixel circuits PCa located in the first circuit area PCA1, the second circuit area PCA2, and the third circuit area PCA3 may drive the display elements that are electrically connected thereto. For example, the display element electrically connected to the pixel circuit PCa located in the first circuit area PCA1 may emit red light. The display element electrically connected to the pixel circuit PCa located in the second circuit area PCA2 may emit green light. The display element electrically connected to the pixel circuit PCa located in the third circuit area PCA3 may emit blue light.

In an embodiment, different second initialization voltages Vaint may be supplied to the first pixel PX1, the second pixel PX2, and the third pixel PX3, by considering light emission characteristics of the first pixel PX1, the second pixel PX2, and the third pixel PX3. For example, the pixel circuit PCa of the first pixel PX1 may be connected to a 2-1^{th} initialization voltage line VL21. The pixel circuit PCa of the second pixel PX2 and the pixel circuit PCa of the third pixel PX3 may be connected to a 2-2^{th} initialization voltage line VL22. A second initialization voltage supplied to the 2-1^{th} initialization voltage line VL21 and a second initialization voltage supplied to the 2-2^{th} initialization voltage line VL22 may be different from each other.

The same elements may be located on each layer for the first circuit area PCA1, the second circuit area PCA2, and the third circuit area PCA3. For convenience, reference numbers may be assigned to the elements of the pixel circuit PCa located in the first circuit area PCA1, and the first circuit area PCA1 may be mainly described in more detail hereinafter. As such, redundant description of the same or substantially the same elements in the second circuit area PCA2 and the third circuit area PCA3 as those described in more detail hereinafter with respect to the first circuit area PCA1 may not be repeated. The cross-sectional views of FIGS. 22 and 25 are cross-sectional views of the first circuit area PCA1.

Referring to FIGS. 10 through 26 together, a first conductive layer 210 may be located on the substrate 100, as shown in FIG. 10. The substrate 100 may include a glass material, a ceramic material, a metal material, or a flexible and/or bendable material. The substrate 100 may have a single-layer structure including an organic layer, or a multi-layered structure including an organic layer and an inorganic layer. For example, the substrate 100 may have a stacked structure including a first base layer, a barrier layer, and a second base layer. Each of the first base layer and the second base layer may be an organic layer including a polymer resin. Each of the first base layer and the second base layer may include a transparent polymer resin. The barrier layer may prevent or substantially prevent penetration of external foreign materials, and may have a single or multi-layered structure including an inorganic material, such as silicon nitride (SiNₓ) or silicon oxide (SiOₓ). In another embodiment, a barrier layer may be further located between the substrate 100 and the first conductive layer 210.

The first conductive layer 210 may extend in the x direction, and may cross the first circuit area PCA1, the second circuit area PCA2, and the third circuit area PCA3. The first conductive layer 210 may correspond to the lower conductive layer DCLb of FIGS. 6A and 6B.

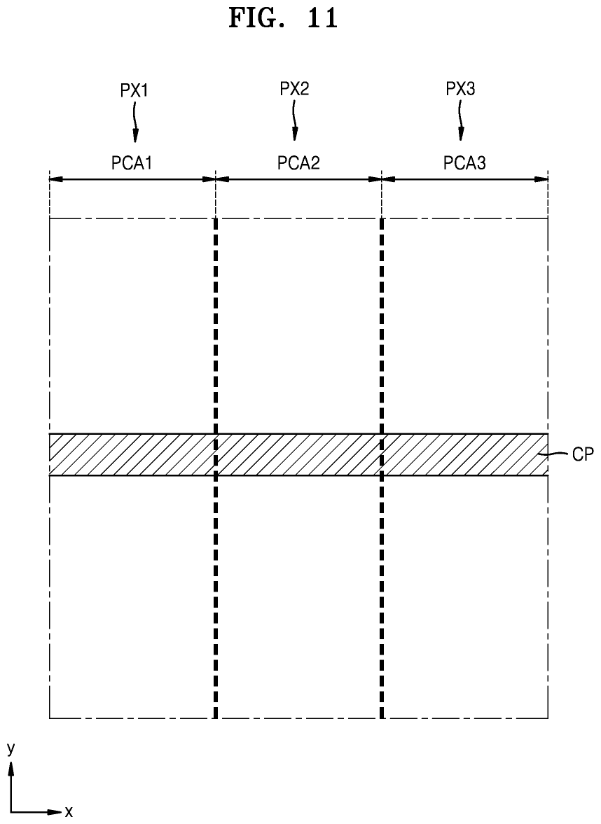

A first insulating layer 111 may be located on the substrate 100 to cover the first conductive layer 210. The semiconductor pattern CP including a silicon semiconductor may be located on the first insulating layer 111 as shown in FIG. 11. The semiconductor pattern CP may extend in the x direction, and may cross the first circuit area PCA1, the second circuit area PCA2, and the third circuit area PCA3. The semiconductor pattern CP may correspond to the semiconductor pattern CP of FIGS. 6A and 6B.

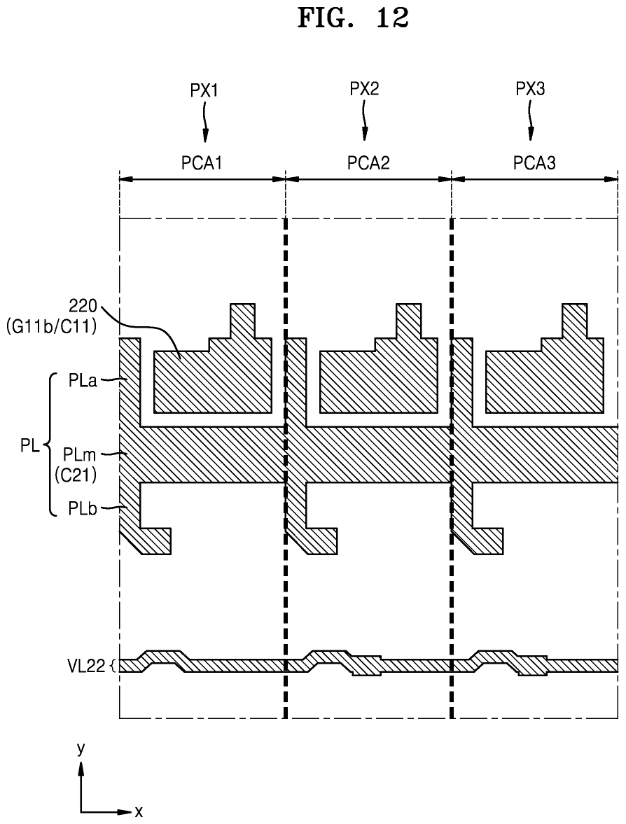

A second insulating layer 112 may be located on the substrate 111 to cover the semiconductor pattern CP, and a second conductive layer may be located on the second insulating layer 112. As shown in FIG. 12, the second conductive layer may include a first electrode layer 220, the driving voltage line PL, and the 2-2^{th} initialization voltage line VL22.

The driving voltage line PL and the 2-2^{th} initialization voltage line VL22 may extend in the x direction, and may cross the first circuit area PCA1, the second circuit area PCA2, and the third circuit area PCA3. The driving voltage line PL may include a protrusion PLa protruding in the +y direction from a main line PLm extending in the x direction, and a protrusion PLb protruding in the −y direction. The protrusion PLa and the protrusion PLb may be located in each circuit area. A part of the driving voltage line PL may include a first electrode C21 of the second capacitor C2. The first electrode layer 220 may be provided in an island shape. The first electrode layer 220 may include a lower electrode G11b of a first gate electrode G11 of the first transistor T1, and a first electrode C11 of the first capacitor C1.

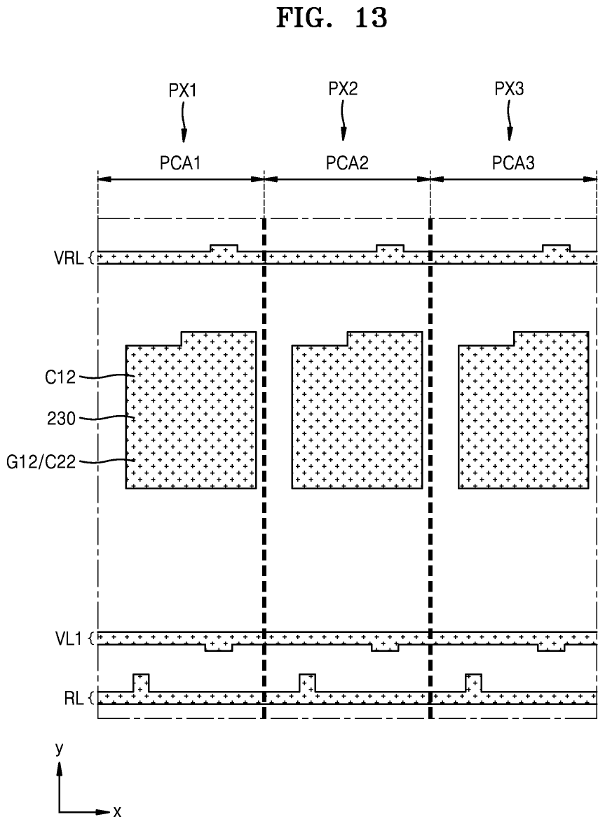

A third insulating layer 113 may be located on the second insulating layer 112 to cover the second conductive layer, and a third conductive layer may be located on the third insulating layer 113. As shown in FIG. 13, the third conductive layer may include a second electrode layer 230, the reference voltage line VRL, and the first initialization voltage line VL1.

The second electrode layer 230 may be provided in an island shape. The second electrode layer 230 may overlap with the first electrode layer 220 and the main line PLm of the driving voltage line PL. A portion of the second electrode layer 230 overlapping with the first electrode layer 220 may include a second electrode C12 of the first capacitor C1. A portion of the second electrode layer 230 overlapping with the main line PLm of the driving voltage line PL may include a second gate electrode G12 of the first transistor T1 and a second electrode C22 of the second capacitor C2.

The reference voltage line VRL and the first initialization voltage line VL1 may extend in the x direction, and may cross the first circuit area PCA1, the second circuit area PCA2, and the third circuit area PCA3.

In an embodiment, the third conductive layer may further include a repair line RL. The repair line RL may extend in the x direction, and may cross the first circuit area PCA1, the second circuit area PCA2, and the third circuit area PCA3.

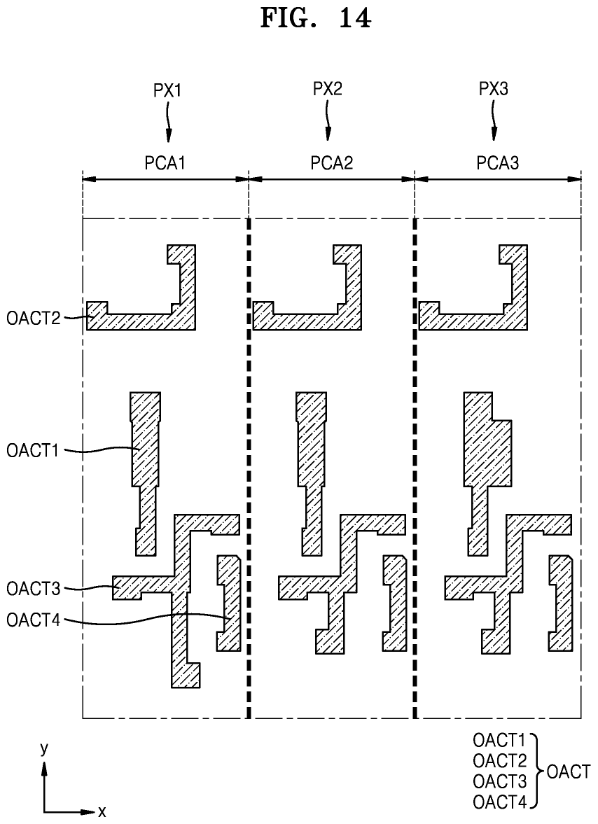

A fourth insulating layer 114 may be located on the third insulating layer 113 to cover the third conductive layer, and the semiconductor layer OACT including an oxide semiconductor may be located on the fourth insulating layer 114 as shown in FIG. 14. The semiconductor layer OACT may include a first semiconductor layer OACT1, a second semiconductor layer OACT2, a third semiconductor layer OACT3, and a fourth semiconductor layer OACT4. The semiconductor layer OACT may include a channel region, and a source region and a drain region on both sides (e.g., opposite sides) of the channel region for each of the first to seventh transistors T1 to T7. The source region or the drain region may be interpreted as a source electrode or a drain electrode of a transistor as necessary or desired.

Referring to FIG. 16, the first semiconductor layer OACT1 may include a source region S1 and a drain region D1 of the first transistor T1, and a source region S5 and a drain region D5 of the fifth transistor T5. The second semiconductor layer OACT2 may include a source region S2 and a drain region D2 of the second transistor T2, and a source region S3 and a drain region D3 of the third transistor T3. The third semiconductor layer OACT3 may include a source region S6 and a drain region D6 of the sixth transistor T6, and a source region S7 and a drain region D7 of the seventh transistor T7. The fourth semiconductor layer OACT4 may include a source region S4 and a drain region D4 of the fourth transistor T4.

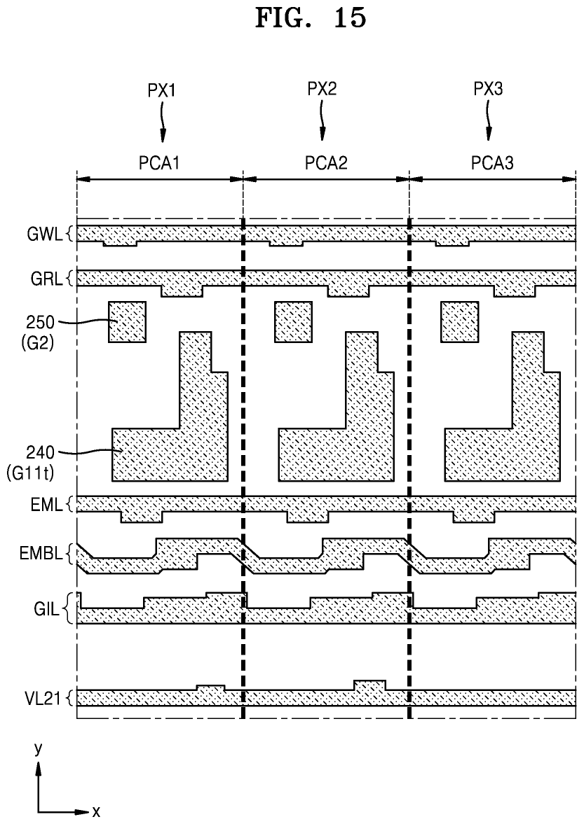

A fifth insulating layer 115 may be located on the fourth insulating layer 114 to cover the semiconductor layer OACT, and a fourth conductive layer may be located on the fifth insulating layer 115. As shown in FIGS. 15 and 16, the fourth conductive layer may include gate electrodes G1 to G7 of the first to seventh transistors T1 to T7. Also, the fourth conductive layer may include the first gate line GWL, the second gate line GIL, the third gate line GRL, the fourth gate line EML, the fifth gate line EMBL, and the 2-1^{th} initialization voltage line VL21.

The gate electrodes G1 to G7 of the first to seventh transistors T1 to T7 may overlap with the channel regions of the semiconductor layer OACT.

Referring to FIG. 16, a third electrode layer 240 may include an upper electrode G11t of the first gate electrode G11 of the first transistor T1. The upper electrode G11t of the first gate electrode G11 may overlap with the first semiconductor layer OACT1. A fourth electrode layer 250 may be the gate electrode G2 of the second transistor T2. The fourth electrode layer 250 may overlap with the second semiconductor layer OACT2. The third electrode layer 240 and the fourth electrode layer 250 may be provided in island shapes. The gate electrode G3 of the third transistor T3 may be a portion of the third gate line GRL overlapping with the second semiconductor layer OACT2. The gate electrode G4 of the fourth transistor T4 may be a portion of the second gate line GIL overlapping with the fourth semiconductor layer OACT4. The gate electrode G5 of the fifth transistor T5 may be a portion of the fourth gate line EML overlapping with the first semiconductor layer OACT1. The gate electrode G6 of the sixth transistor T6 may be a portion of the fifth gate line EMBL overlapping with the third semiconductor layer OACT3. The gate electrode G7 of the seventh transistor T7 may be a portion of the second gate line GIL overlapping with the third semiconductor layer OACT3.

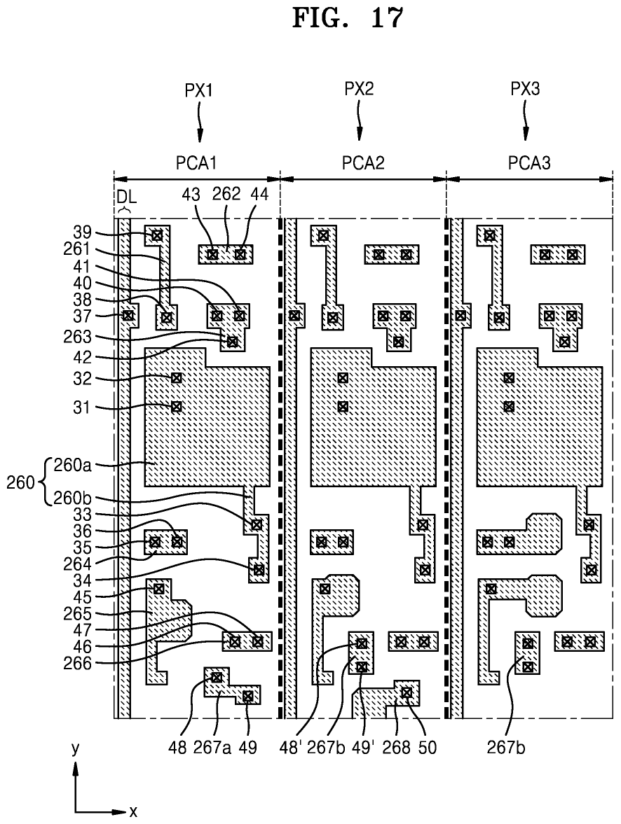

A sixth insulating layer 116 may be located on the fifth insulating layer 115 to cover the fourth conductive layer, and a fifth conductive layer may be located on the sixth insulating layer 116. As shown in FIG. 17, the fifth conductive layer may include the data line DL and connection electrodes 260, 261, 262, 263, 264, 265, 266, 267a, 267b, and 268.

The data line DL may extend in the y direction, and may be located in each circuit area. The data line DL may be electrically connected to the drain region D2 of the second transistor T2 through a contact hole 37 passing through (e.g., penetrating) the fifth insulating layer 115 and the sixth insulating layer 116.

The connection electrode 260 may include a first area 260a overlapping with the second electrode layer 230 and the third electrode layer 240, and a second area 260b protruding in the −y direction from the first area 260a. The connection electrode 260 may electrically connect the source region S1 of the first transistor T1 to the fourth transistor T4 and the sixth transistor T6.

The first area 260a of the connection electrode 260 may be electrically connected to the source region S1 of the first transistor T1 through a contact hole 31 passing through (e.g., penetrating) the fifth insulating layer 115 and the sixth insulating layer 116. The first area 260a of the connection electrode 260 may be electrically connected to the second electrode layer 230 through a contact hole 32 passing through (e.g., penetrating) the fourth insulating layer 114, the fifth insulating layer 115, and the sixth insulating layer 116. Accordingly, the second electrode layer 230 may be a source electrode electrically connected to the source region S1 of the first transistor T1. The second area 260b of the connection electrode 260 may be electrically connected to the drain region D6 of the sixth transistor T6 through a contact hole 33 passing through (e.g., penetrating) the fifth insulating layer 115 and the sixth insulating layer 116. The second area 260b of the connection electrode 260 may be electrically connected to the drain region D4 of the fourth transistor T4 through a contact hole 34 passing through (e.g., penetrating) the fifth insulating layer 115 and the sixth insulating layer 116.

The connection electrode 261 may be electrically connected to the gate electrode G2 of the second transistor T2 through a contact hole 38 passing through (e.g., penetrating) the sixth insulating layer 116. The connection electrode 261 may be electrically connected to the first gate line GWL through a contact hole 39 passing through (e.g., penetrating) the sixth insulating layer 116.

The connection electrode 262 may be electrically connected to the source region S3 of the third transistor T3 through a contact hole 43 passing through (e.g., penetrating) the fifth insulating layer 115 and the sixth insulating layer 116. The connection electrode 262 may be electrically connected to the reference voltage line VRL through a contact hole 44 passing through (e.g., penetrating) the fourth insulating layer 114, the fifth insulating layer 115, and the sixth insulating layer 116.

The connection electrode 263 may be electrically connected to the source region S2 of the second transistor T2 and the drain region D3 of the third transistor T3 through a contact hole 40 passing through (e.g., penetrating) the fifth insulating layer 115 and the sixth insulating layer 116. The connection electrode 263 may be electrically connected to the first electrode layer 220 through a contact hole 41 passing through (e.g., penetrating) the third insulating layer 113, the fourth insulating layer 114, the fifth insulating layer 115, and the sixth insulating layer 116, and may be electrically connected to the lower electrode G11b of the first gate electrode G11 of the first transistor T1. The connection electrode 263 may be electrically connected to the third electrode layer 240 through a contact hole 42 passing through (e.g., penetrating) the sixth insulating layer 116, and may be electrically connected to the upper electrode G11t of the first gate electrode G11 of the first transistor T1.

The connection electrode 264 may be electrically connected to the protrusion PLb of the driving voltage line PL through a contact hole 35 passing through (e.g., penetrating) the third insulating layer 113, the fourth insulating layer 114, the fifth insulating layer 115, and the sixth insulating layer 116. The connection electrode 264 may be electrically connected to the drain region D5 of the fifth transistor T5 through a contact hole 36 passing through (e.g., penetrating) the fifth insulating layer 115 and the sixth insulating layer 116. Accordingly, the drain region D5 of the fifth transistor T5 may be electrically connected to the driving voltage line PL.

The connection electrode 265 may be electrically connected to the source region S6 of the sixth transistor T6 and the drain region D7 of the seventh transistor T7 through a contact hole 45 passing through (e.g., penetrating) the fifth insulating layer 115 and the sixth insulating layer 116. The connection electrode 265 may overlap with a part of the repair line RL. The connection electrode 265 may be insulated from the repair line RL, and may be subsequently electrically connected to the repair line RL if a defect occurs in a pixel circuit located in a corresponding circuit area.

The connection electrode 266 may be electrically connected to the source region S4 of the fourth transistor T4 through a contact hole 47 passing through (e.g., penetrating) the fifth insulating layer 115 and the sixth insulating layer 116. The connection electrode 266 may be connected to the first initialization voltage line VL1 through a contact hole 46 passing through (e.g., penetrating) the fourth insulating layer 114, the fifth insulating layer 115, and the sixth insulating layer 116.

The connection electrode 267a located in the first circuit area PCA1 may be electrically connected to the source region S7 of the seventh transistor T7 through a contact hole 48 passing through (e.g., penetrating) the fifth insulating layer 115 and the sixth insulating layer 116. The connection electrode 267a may be connected to the 2-1^{th} initialization voltage line VL21 through a contact hole 49 passing through (e.g., penetrating) the fourth insulating layer 114, the fifth insulating layer 115, and the sixth insulating layer 116. The connection electrode 267b located in each of the second circuit area PCA2 and the third circuit area PCA3 may be electrically connected to the source region S7 of the corresponding seventh transistor T7 through a corresponding contact hole 48′ passing through (e.g., penetrating) the fifth insulating layer 115 and the sixth insulating layer 116. The connection electrode 267b may be electrically connected to the 2-2^{th} initialization voltage line VL22 through a contact hole 49′ passing through (e.g., penetrating) the fourth insulating layer 114, the fifth insulating layer 115, and the sixth insulating layer 116.

The connection electrode 268 may be electrically connected to the 2-1^{th} initialization voltage line VL21 through a contact hole 50 passing through (e.g., penetrating) the fourth insulating layer 114, the fifth insulating layer 115, and the sixth insulating layer 116. The connection electrode 268 may be located in some of the second circuit areas PCA2.

The first gate line GWL, the second gate line GIL, the third gate line GRL, the fourth gate line EML, the fifth gate line EMBL, and the 2-1^{th} initialization voltage line VL21 may extend in the x direction, and may be located in the first circuit area PCA1, the second circuit area PCA2, and the third circuit area PCA3. The 2-1^{th} initialization voltage line VL21 may overlap with the repair line RL.

As shown in FIG. 25, the main line PLm of the driving voltage line PL and the second electrode layer 230 overlapping with the main line PLm may constitute the second capacitor C2. The third electrode layer 240 and the first area 260a of the connection electrode 260 overlapping with the third electrode layer 240 may constitute a 1-1^{th} capacitor C1a. The first electrode layer 220 and the second electrode layer 230 overlapping with the first electrode layer 220 may constitute a 1-2^{th} capacitor C1b. Due to parallel connection of the 1-1^{th} capacitor C1a and the 1-2^{th} capacitor C1b, a capacitance of the first capacitor C1 may be a sum of a capacitance of the 1-1^{th} capacitor C1a and a capacitance of the 1-2^{th} capacitor C1b. Because the 1-1^{th} capacitor C1a and the 1-2^{th} capacitor C1b vertically overlap with each other, a capacitance may be increased (e.g., ensured) without increasing the area of the first capacitor C1 in the x direction.

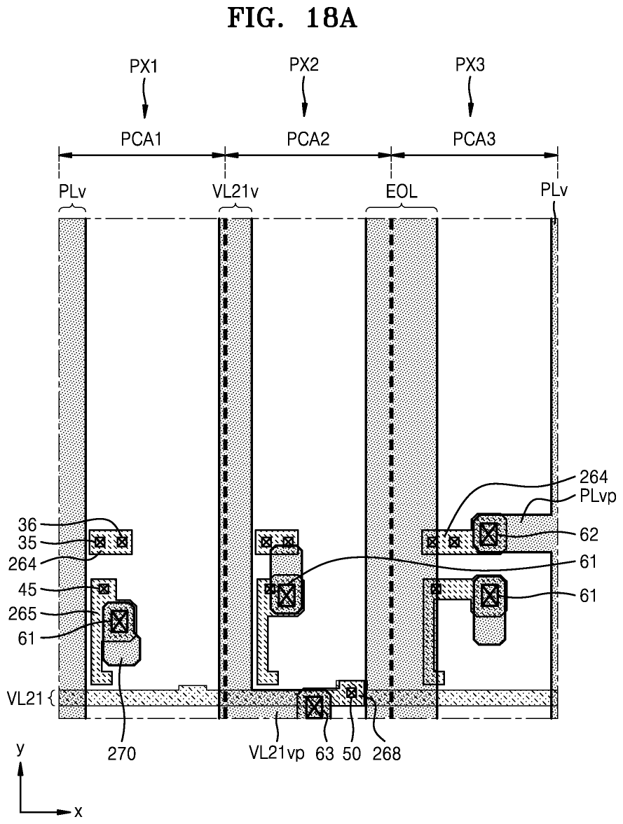

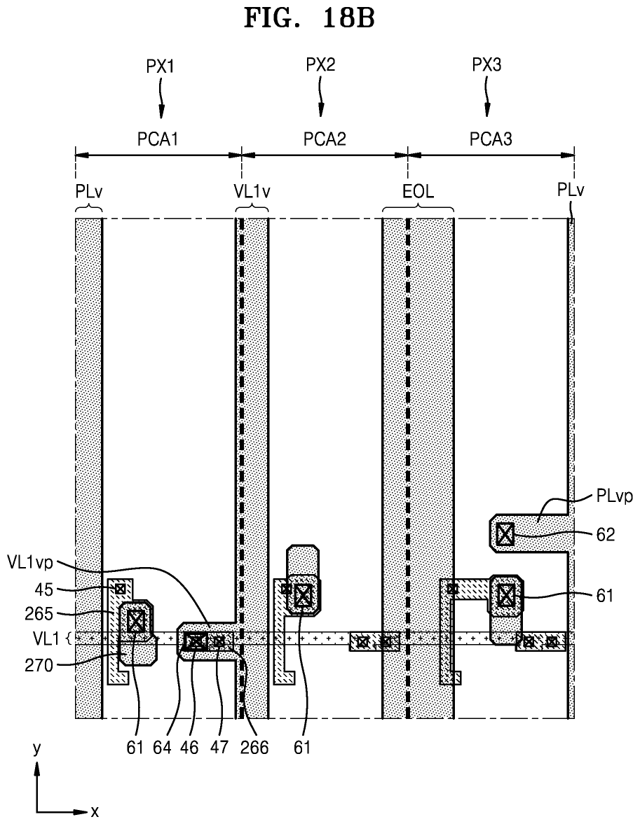

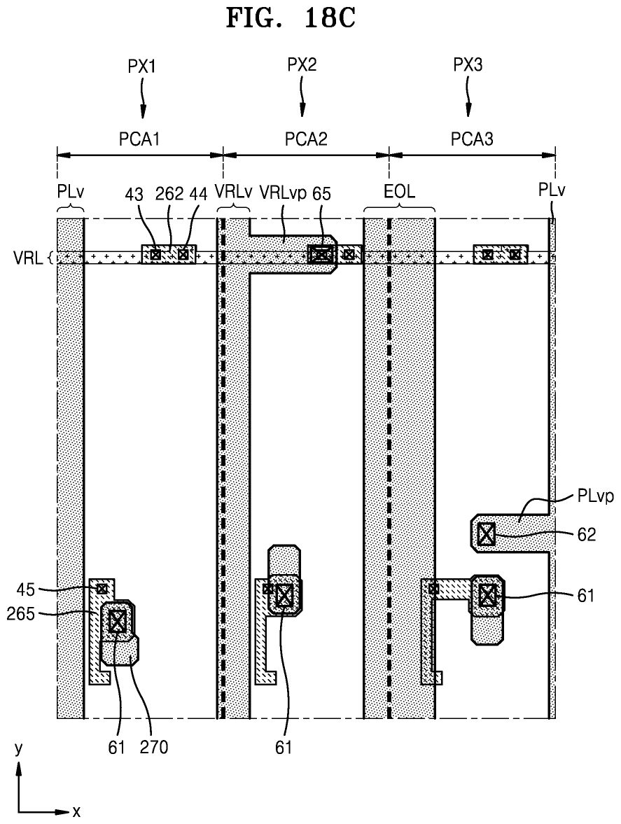

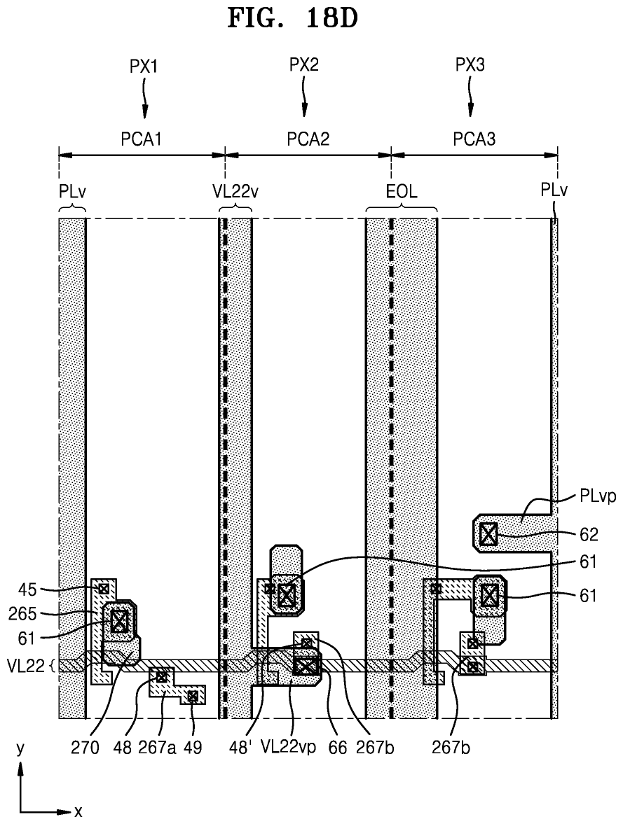

A seventh insulating layer 117 may be located on the sixth insulating layer 116 to cover the fifth conductive layer, and a sixth conductive layer may be located on the seventh insulating layer 117. As shown in FIGS. 18A through 18D, the sixth conductive layer may include a plurality of vertical conductive lines and a connection electrode 270. For convenience of illustration, only some of the fifth conductive layer and the lower conductive layers are illustrated in FIGS. 18A through 18D.

The connection electrode 270 may be electrically connected to the connection electrode 265 through a contact hole 61 passing through (e.g., penetrating) the seventh insulating layer 117, and may be electrically connected to the source region S6 of the sixth transistor T6.

The vertical conductive lines may include a vertical driving voltage line PLv, vertical initialization voltage lines, a common voltage line EOL, and a vertical reference voltage line VRLv. The vertical initialization voltage lines may include a first vertical initialization voltage line VL1v, a 2-1^{th} vertical initialization voltage line VL21v, and a 2-2^{th} vertical initialization voltage line VL22v. The vertical driving voltage line PLv, the vertical initialization voltage lines, the common voltage line EOL, and the vertical reference voltage line VRLv may extend in the y direction, and may be spaced apart from each other along the x direction in the first circuit area PCA1, the second circuit area PCA2, and the third circuit area PCA3.

As shown in FIG. 19, in each unit pixel area PCAu, the vertical driving voltage line PLv, one of the first vertical initialization voltage lines VL1v, the 2-1^{th} vertical initialization voltage line VL21v, the 2-2^{th} vertical initialization voltage line VL22v, the vertical reference voltage line VRLv, and the common voltage line EOL may be sequentially and repeatedly located along the x direction. For example, in the x direction, the vertical conductive lines may be arranged in the order of the vertical driving voltage line PLv, the first vertical initialization voltage line VL1v, the common voltage line EOL, the vertical driving voltage line PLv, the 2-1^{th} vertical initialization voltage line VL21v, the common voltage line EOL, the vertical driving voltage line PLv, the vertical reference voltage line VRLv, the common voltage line EOL, the vertical driving voltage line PLv, the 2-2^{th} vertical initialization voltage line VL22v, and the common voltage line EOL. The vertical conductive lines may be electrically connected to horizontal conductive line extending in the x direction. The horizontal conductive lines may include the driving voltage line PL, the first initialization voltage line VL1, the 2-1^{th} initialization voltage line VL21, the 2-2^{th} initialization voltage line VL22, and the reference voltage line VRL.

FIG. 18A illustrates an example where the vertical driving voltage line PLv, the 2-1^{th} vertical initialization voltage line VL21v, and the common voltage line EOL are sequentially located along the x direction in the unit pixel area PCAu.

The vertical driving voltage line PLv may be located at a boundary between the third circuit area PCA3 and the first circuit area PCA1. The 2-1^{th} vertical initialization voltage line VL21v may be located at a boundary between the first circuit area PCA1 and the second circuit area PCA2. The common voltage line EOL may be located at a boundary between the second circuit area PCA2 and the third circuit area PCA3.

The vertical driving voltage line PLv may overlap with the data line DL located in the first circuit area PCA1. The vertical driving voltage line PLv may include a protrusion PLvp protruding in a −x direction and overlapping with the third circuit area PCA3. The protrusion PLvp may be electrically connected to the connection electrode 264 located in the third circuit area PCA3 through a contact hole 62 passing through (e.g., penetrating) the seventh insulating layer 117. Because the connection electrode 264 is electrically connected to the driving voltage line PL, the vertical driving voltage line PLv may be electrically connected to the driving voltage line PL, and the driving voltage line PL may have a mesh structure in the display area DA.

The 2-1^{th} vertical initialization voltage line VL21v may overlap with the data line DL located in the second circuit area PCA2. The 2-1^{th} vertical initialization voltage line VL21v may include a protrusion VL21vp protruding in the +x direction and overlapping with the second circuit area PCA2. The protrusion VL21vp may be electrically connected to the connection electrode 268 located in the second circuit area PCA2 through a contact hole 63 passing through (e.g., penetrating) the seventh insulating layer 117. Because the connection electrode 268 is electrically connected to the 2-1^{th} initialization voltage line VL21, the 2-1^{th} vertical initialization voltage line VL21v may be electrically connected to the 2-1^{th} initialization voltage line VL21, and the 2-1^{th} initialization voltage line VL21 may have a mesh structure in the display area DA.

The common voltage line EOL may overlap with the data line DL located in the third circuit area PCA3. The common voltage lines EOL may be electrically connected to the common voltage supply line 113 located in the peripheral area PA. In an embodiment, the counter electrode may be electrically connected to the common voltage lines EOL at regular intervals in the display area DA.

FIG. 18B illustrates an example in which the vertical driving voltage line PLv, the first vertical initialization voltage line VL1v, and the common voltage line EOL are sequentially located along the x direction in the unit circuit area PCAu.

The first vertical initialization voltage line VL1v may overlap with the data line DL located in the second circuit area PCA2. The first vertical initialization voltage line VL1v may include a protrusion VL1vp protruding in the −x direction and overlapping with the first circuit area PCA1. The protrusion VL1vp may be electrically connected to the connection electrode 266 located in the first circuit area PCA1 through a contact hole 64 passing through (e.g., penetrating) the seventh insulating layer 117. Because the connection electrode 266 is electrically connected to the first initialization voltage line VL1, the first vertical initialization voltage line VL1v may be electrically connected to the first initialization voltage line VL1, and the first initialization voltage line VL1 may have a mesh structure in the display area DA.

FIG. 18C illustrates an example in which the vertical driving voltage line PLv, the vertical reference voltage line VRLv, and the common voltage line EOL are sequentially located along the x direction in the unit circuit area PCAu.

The vertical reference voltage line VRLv may overlap with the data line DL located in the second circuit area PCA2. The vertical reference voltage line VRLv may include a protrusion VRLvp protruding in the +x direction and overlapping with the second circuit area PCA2. The protrusion VRLvp may be electrically connected to the connection electrode 262 located in the second circuit area PCA2 through a contact hole 65 passing through (e.g., penetrating) the seventh insulating layer 117. Because the connection electrode 262 is electrically connected to the reference voltage line VRL, the vertical reference voltage line VRLv may be electrically connected to the reference voltage line VRL, and the reference voltage line VRL may have a mesh structure in the display area DA.

FIG. 18D illustrates an example in which the vertical driving voltage line PLv, the 2-2^{th} vertical initialization voltage line VL22v, and the common voltage line EOL are sequentially located along the x direction in the unit circuit area PCAu.

The 2-2^{th} vertical initialization voltage line VL22v may overlap with the data line DL located in the second circuit area PCA2. The 2-2^{th} vertical initialization voltage line VL22v may include a protrusion VL22vp protruding in the +x direction and overlapping with the second circuit area PCA2. The protrusion VL22vp may be electrically connected to the connection electrode 267b located in the second circuit area PCA2 through a contact hole 66 passing through (e.g., penetrating) the seventh insulating layer 117. Because the connection electrode 267b is electrically connected to the 2-2^{th} initialization voltage line VL22, the 2-2^{th} vertical initialization voltage line VL22v may be electrically connected to the 2-2^{th} initialization voltage line VL22, and the 2-2^{th} initialization voltage line VL22 may have a mesh structure in the display area DA.

In some embodiments, voltage supply lines electrically connected to the horizontal conductive lines and/or the vertical conductive lines may be further located in the peripheral area PA. The voltage supply lines may be located on at least one of an upper side, a lower side, a left side, and/or a right side of the display area PA.

Shapes and positions of the connection electrodes corresponding to the first circuit area PCA1, the second circuit area PCA2, and the third circuit area PCA3 may be variously modified according to positions of the conductive lines located in the circuit areas.

FIG. 20 illustrates the pixel circuits located in the first circuit area PCA1, the second circuit area PCA2, and the third circuit area PCA3 of FIG. 18A. FIG. 21, which is an enlarged view of the portion A of FIG. 6A, illustrates a pixel located at an edge of the display area DA, and conductive layers located around the pixel.

As described above, in the display area DA, the semiconductor pattern CP may extend in the x direction and may be located in each row, and the main line PLm of the driving voltage line PL may extend in the x direction and may be located in each row to overlap with the semiconductor pattern CP. As shown in FIGS. 21 and 22, at an edge of the display area DA, an end of the first conductive layer 210, an end of the semiconductor pattern CP, an end of the main line PLm of the driving voltage line PL, and the protrusion PLvp of the vertical driving voltage line PLv may sequentially overlap with each other in the z direction, and may be electrically connected to each other through a connection electrode 269.

The connection electrode 269 may be located at (e.g., in or on) a layer between the end of the main line PLm of the driving voltage line PL and the semiconductor pattern CP. For example, the connection electrode 269 may be located between the sixth insulating layer 116 and the seventh insulating layer 117. The protrusion PLvp of the vertical driving voltage line PLv may be electrically connected to the connection electrode 269 through a contact hole 81 passing through (e.g., penetrating) the seventh insulating layer 117. The connection electrode 269 may be electrically connected to the end of the main line PLm of the driving voltage line PL through a contact hole 82 passing through (e.g., penetrating) the third to sixth insulating layers 113, 114, 115, and 116. The connection electrode 269 may be electrically connected to the end of the semiconductor pattern CP through a contact hole 83 passing through (e.g., penetrating) the second to sixth insulating layers 112, 113, 114, 115, and 116. The connection electrode 269 may be electrically connected to the end of the first conductive layer 210 through a contact hole 84 passing through (e.g., penetrating) the first to sixth insulating layers 111, 112, 113, 114, 115, and 116.

The description above with respect to the embodiment of FIG. 21 may apply to a pixel located in a last column and conductive layers located around the pixel, and thus, redundant description thereof may not be repeated.

The semiconductor pattern CP, the main line PLm of the driving voltage line PL, and the first conductive layer 210 may correspond to a semiconductor layer (e.g., the semiconductor pattern CP), a top gate electrode (e.g., the upper conductive layer DCLt), and a bottom gate electrode (e.g., the lower conductive layer DCLb), respectively, of the 4-terminal silicon thin-film transistor TRs located in each row as described above with reference to FIGS. 6A to 6C. The vertical driving voltage line PLv may correspond to the signal line SCL for receiving the driving voltage ELVDD as described above with reference to FIGS. 6A to 6C.

In an embodiment, the semiconductor pattern CP may be located in the display area DA to overlap with a part of the pixel circuit PCa, and the 4-terminal silicon thin-film transistor TRs including the semiconductor pattern CP may be provided in each row to overlap with a part of the pixel circuit PCa. As shown in FIGS. 20 and 25, the 4-terminal silicon thin-film transistor TRs may overlap with the first transistor T1, the first capacitor C1, and the second capacitor C2 of the pixel circuit PCa.

An eighth insulating layer 118 may be located on the seventh insulating layer 117 to cover the sixth conductive layer, and the organic light-emitting diode OLED may be located as the display element on the eighth insulating layer 118. The organic light-emitting diode OLED may include a pixel electrode 311, a counter electrode 315, and an intermediate layer between the pixel electrode 311 and the counter electrode 315.

The pixel electrode 311 may be electrically connected to the connection electrode 270 that is a lower conductive pattern through a contact hole 71 of the eighth insulating layer 118, and may be connected to the first transistor T1. As shown in FIG. 23, the pixel electrode 311 connected to a pixel circuit of the first pixel PX1 may be electrically connected to the connection electrode 270 located in the first circuit area PCA1, and may be connected to the first transistor T1. The pixel electrode 311 connected to a pixel circuit of the second pixel PX2 may be electrically connected to the connection electrode 270 located in the second circuit area PCA2, and may be connected to the first transistor T1. The pixel electrode 311 connected to a pixel circuit of the third pixel PX3 may be electrically connected to the connection electrode 270 located in the third circuit area PCA3, and may be connected to the first transistor T1.

As shown in FIG. 25, a ninth insulating layer 119 that is a pixel-defining layer covering an edge of the pixel electrode 311 may be located on the pixel electrode 311. An opening 119OP through which a part of the pixel electrode 311 is exposed and an emission area is defined may be defined in the ninth insulating layer 119. The ninth insulating layer 119 may have a single or multi-layered structure including an organic insulating layer and/or an inorganic insulating layer.

The intermediate layer may include an emission layer 313, and a first functional layer over the emission layer 313 and/or a second functional layer under the emission layer 313. The first functional layer may be a hole transport layer (HTL). As another example, the first functional layer may include a hole injection layer (HIL) and an HTL. The second functional layer may include an electron transport layer (ETL) and/or an electron injection layer (EIL). The first functional layer and the second functional layer may each be integrally formed to correspond to a plurality of organic light-emitting diodes OLED included in the display area DA. The first functional layer or the second functional layer may be omitted as needed or desired. FIG. 23 illustrates an emission layer 313a of the organic light-emitting diode OLED electrically connected to the pixel circuit located in the first circuit area PCA1, an emission layer 313b of the organic light-emitting diode OLED electrically connected to the pixel circuit located in the second circuit area PCA2, and an emission layer 313c of the organic light-emitting diode OLED electrically connected to the pixel circuit located in the third circuit area PCA3.

FIG. 24 illustrates the pixel electrode 311 and an emission area EA of each of the first pixel PX1, the second pixel PX2, and the third pixel PX3. The emission area EA is an area where the emission layer 313 of the organic light-emitting diode OLED is located. The emission area EA may be defined by the opening 119OP of the ninth insulating layer 119. Because the emission layer 313 is located on the pixel electrode 311, an arrangement of the emission areas EA of FIG. 24 may be an arrangement of the pixel electrodes or an arrangement of the pixels.

The emission area EA may have a polygonal shape, such as a quadrangular shape or an octagonal shape, a circular shape, or an elliptical shape. The polygonal shape may include a shape having rounded corners (e.g., rounded vertices).

As shown in FIG. 24, the emission area EA of the first pixel PX1 and the emission area EA of the second pixel PX2 may be located to be adjacent to each other in the y direction. The emission area EA of the third pixel PX3 may be located to be adjacent to the emission area EA of the first pixel PX1 and the emission area EA of the second pixel PX2 in the x direction. Accordingly, the emission area EA of the first pixel PX1 and the emission area EA of the second pixel PX2 may be alternately located along the y direction along a virtual straight line ISL1, and the emission area EA of the third pixel PX3 may be repeatedly located along the y direction along a virtual straight line ISL2.

Lengths of the emission area EA of the first pixel PX1, the emission area EA of the second pixel PX2, and the emission area EA of the third pixel PX3 in the x direction and the y direction may be the same or substantially the same as each other or may be different from each other. For example, the emission area EA of the first pixel PX1 may have a square shape, and the emission area EA of the second pixel PX2 and the emission area EA of the third pixel PX3 may have a rectangular shape with a long side extending in the y direction. A length of the emission area EA of the third pixel PX3 in the y direction may be equal to or greater than a sum of a length of the emission area EA of the first pixel PX1 in the y direction and a length of the emission area EA of the second pixel PX2 in the y direction.

The first emission area EA of the first pixel PX1, the second emission area EA of the second PX2, and the third emission area EA of the third pixel PX3 may have different areas (e.g., sizes) from each other. In an embodiment, the emission area EA of the third pixel PX3 may have a larger area than that of the emission area EA of the first pixel PX1. The emission area EA of the third pixel PX3 may have a larger area than that of the emission area EA of the second pixel PX2. The emission area EA of the second pixel PX2 may have a larger area than that of the emission area EA of the first pixel PX1.

The counter electrode 315 may be integrally formed to correspond to a plurality of organic light-emitting diodes OLED included in the display area DA.

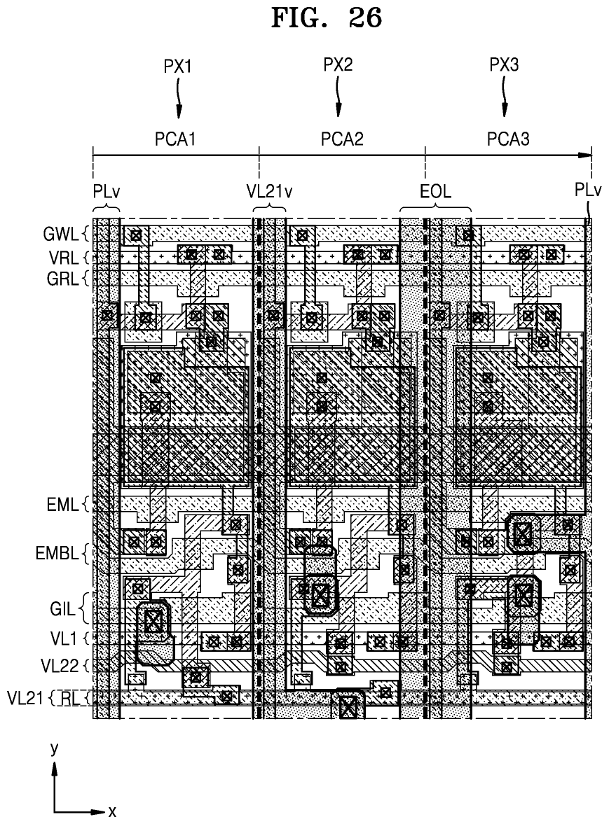

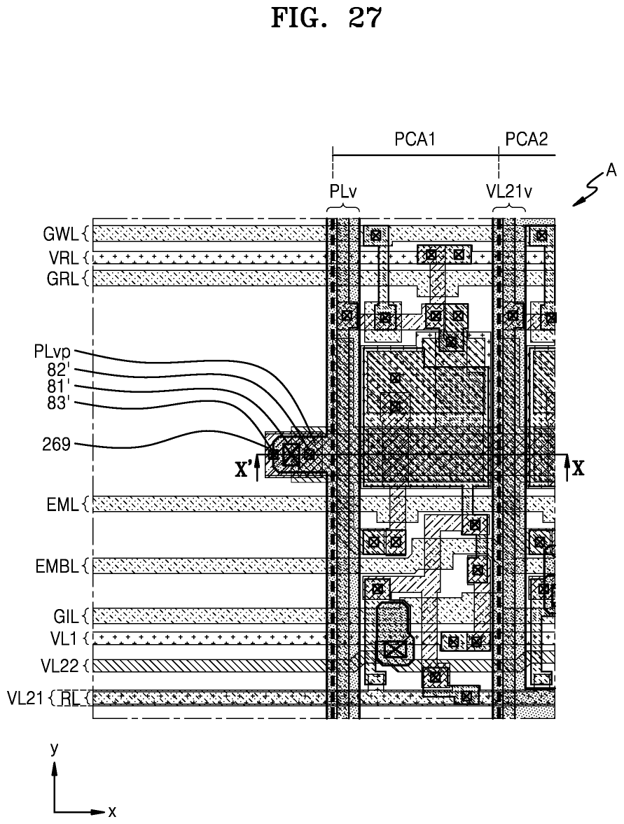

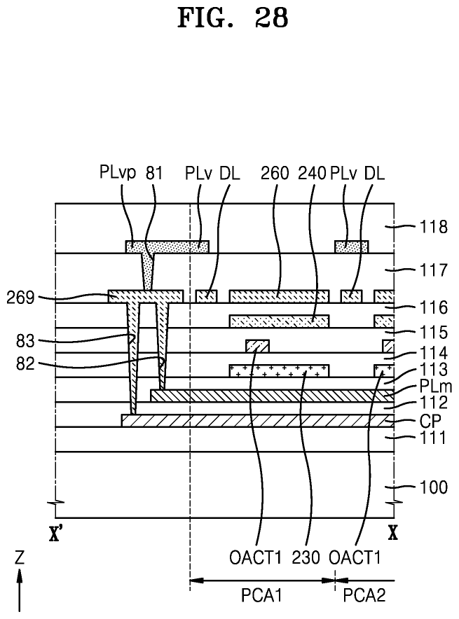

FIG. 26 is a view schematically illustrating transistors and capacitors of the pixel of FIG. 9. FIG. 27 is a view schematically illustrating conductive layers at an edge of a display area. FIG. 28 is a cross-sectional view taken along the line X-X′ of FIG. 27. FIG. 27 is an enlarged view of the portion A of FIG. 6A.

In FIGS. 26 through 28, the same or substantially the same elements as those described above with reference to FIGS. 10 through 25 are denoted by the same reference numerals, and thus, redundant description thereof may not be repeated. In FIG. 26, the reference numerals of some of the same or substantially the same elements as those described above with reference to FIGS. 10 through 25 may be omitted. The display apparatus of FIGS. 26 and 27 is the same or substantially the same as (or similar to) the display apparatus described above with reference to FIGS. 20 and 21, except that the first conductive layer 210 in the display apparatus described above with reference to FIGS. 10 through 25 is omitted. As such, the differences from the embodiments described above with reference to FIGS. 10 through 25 will be mainly described hereinafter.

As shown in FIGS. 26 and 28, in the display area DA, the semiconductor pattern CP may extend in the x direction, and may be located in each row. The main line PLm of the driving voltage line PL may extend in the x direction, and may be located in each row to overlap with the semiconductor pattern CP. As shown in FIGS. 27 and 28, around a pixel of a first column and a pixel of a last column located at an edge of the display area DA, an end of the semiconductor pattern CP, an end of the main line PLm of the driving voltage line PL, and the protrusion PLvp of the vertical driving voltage line PLv may sequentially overlap with each other in the z direction, and may be electrically connected to each other through the connection electrode 269.

The protrusion PLvp of the vertical driving voltage line PLv may be electrically connected to the connection electrode 269 through the contact hole 81 passing through (e.g., penetrating) the seventh insulating layer 117. The connection electrode 269 may be electrically connected to the end of the main line PLm of the driving voltage line PL through the contact hole 82 passing through (e.g., penetrating) the third to sixth insulating layers 113, 114, 115, and 116. The connection electrode 269 may be electrically connected to the end of the semiconductor pattern CP through the contact hole 83 passing through (e.g., penetrating) the second to sixth insulating layers 112, 113, 114, 115, and 116.

The semiconductor pattern CP and the main line PLm of the driving voltage line PL may correspond to a semiconductor layer (e.g., the semiconductor pattern CP) and a gate electrode (e.g., the conductive layer DCL) of the 3-terminal silicon thin-film transistor TRs provided in each row as described above with reference to FIGS. 4A through 4C. The vertical driving voltage line PLv may correspond to the signal line SCL for receiving the driving voltage ELVDD as described above with reference to FIGS. 4A through 4C.

In an embodiment, the semiconductor pattern CP and the 3-terminal silicon thin-film transistor TRs including the semiconductor pattern CP may be provided in each row to overlap with a part of the pixel circuit PCa. As shown in FIG. 26, the 3-terminal silicon thin-film transistor TRs may overlap with the first transistor T1, the first capacitor C1, and the second capacitor C2 of the pixel circuit PCa.

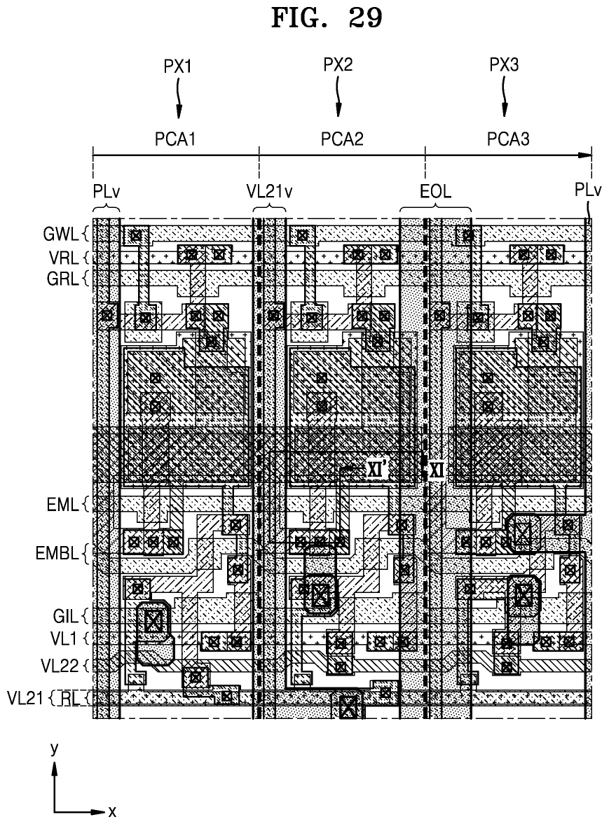

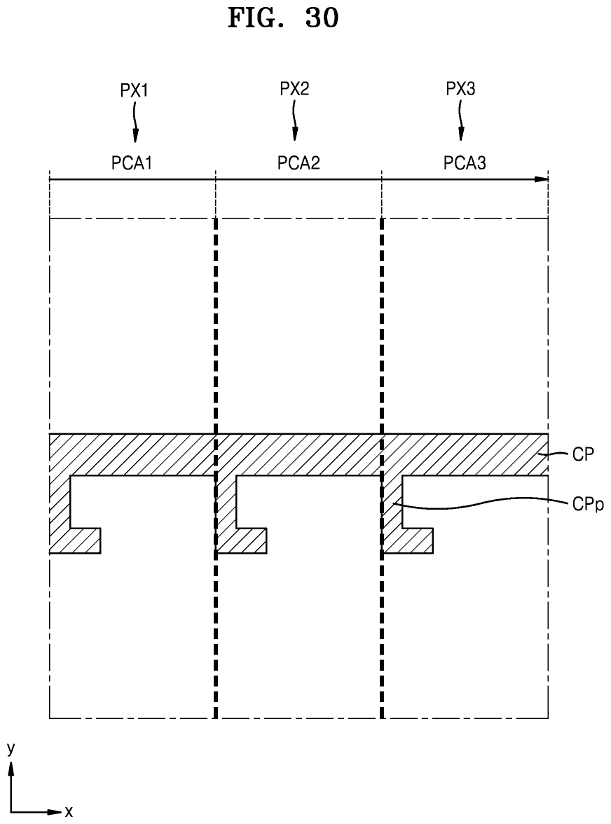

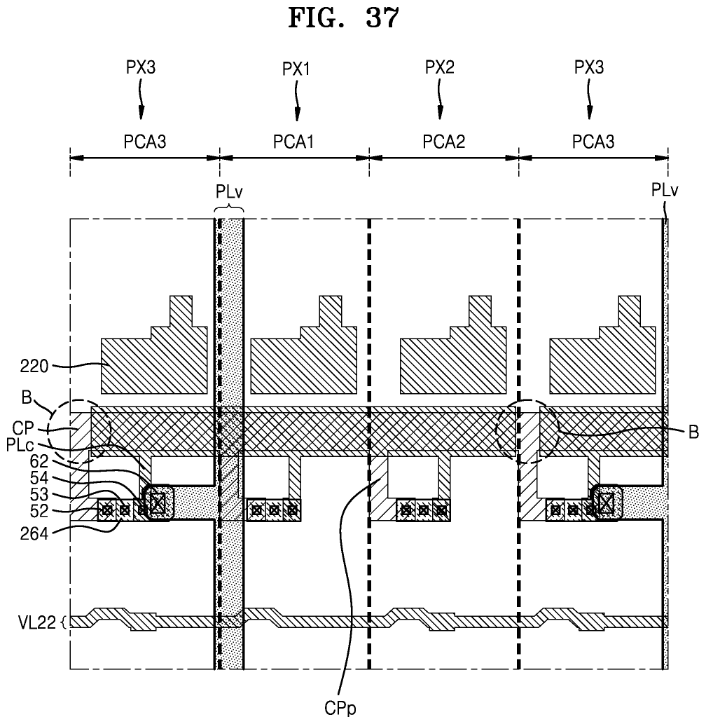

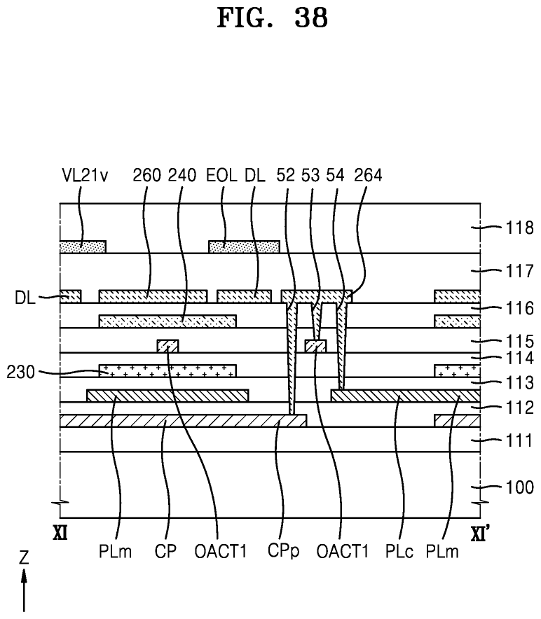

FIG. 29 is a view schematically illustrating transistors and capacitors of the pixel of FIG. 9, according to an embodiment. FIGS. 30 through 36 are views schematically illustrating elements according to layers of a pixel circuit of FIG. 29. FIG. 37 is a layout view illustrating some elements of FIG. 29. FIG. 38 is a cross-sectional view taken along the line XI-XI′ of FIG. 29. FIG. 38 is a cross-sectional view illustrating some of the elements located in the second circuit area PCA2.

In FIGS. 29 through 38, the same or substantially the same elements as those described above with reference to FIGS. 10 through 25 are denoted by the same reference numerals, and thus, redundant description thereof may not be repeated. In FIG. 29, the reference numerals of some of the same or substantially the same elements as those described above with reference to FIGS. 10 through 25 may be omitted. The elements of the display apparatus of FIG. 29 are the same or substantially the same as (or similar to) those of the display apparatus described above with reference to FIG. 20, except that the first conductive layer 210 is omitted and the semiconductor pattern CP and the driving voltage line PL are modified. As such, the differences from the embodiments described above with reference to FIGS. 10 through 25 will be mainly described hereinafter.

The first insulating layer 111 may be located on the substrate 100, and as shown in FIG. 30, the semiconductor pattern CP including a silicon semiconductor may be located on the first insulating layer 111. The semiconductor pattern CP may extend in the x direction, and may cross the first circuit area PCA1, the second circuit area PCA2, and the third circuit area PCA3. The semiconductor pattern CP may correspond to the semiconductor pattern CP described above with reference to FIGS. 5A and 5B. The semiconductor pattern CP may include a protrusion CPp protruding in the −y direction in each circuit area.

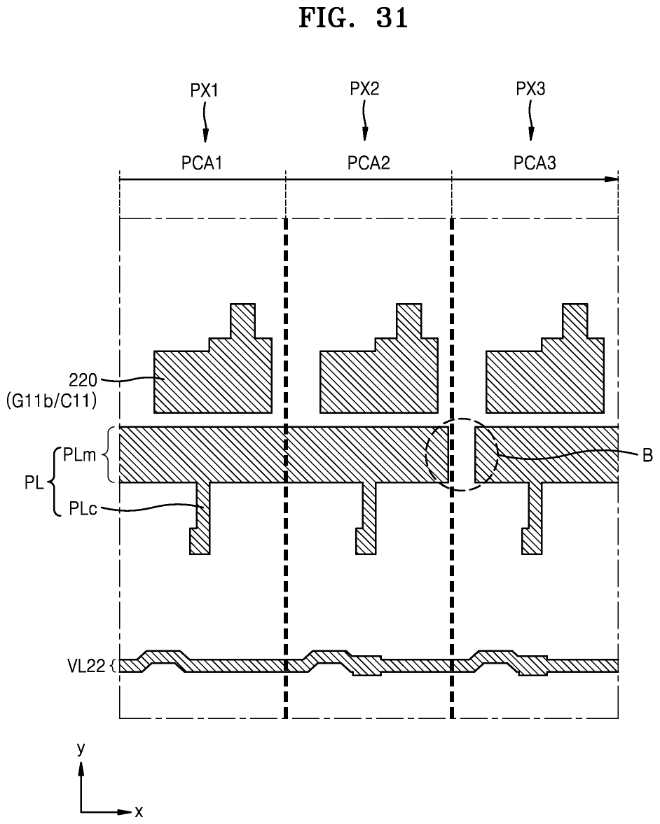

The second insulating layer 112 may be located on the first insulating layer 111 to cover the semiconductor pattern CP, and the second conductive layer may be located on the second insulating layer 112. As shown in FIG. 31, the second conductive layer may include the first electrode layer 220, the driving voltage line PL, and the 2-2^{th} initialization voltage line VL22.

The driving voltage line PL and the 2-2^{th} initialization voltage line VL22 may extend in the x direction, and may cross the first circuit area PCA1, the second circuit area PCA2, and the third circuit area PCA3. The driving voltage line PL may include a plurality of sub-lines that are spaced apart (e.g., separated) from each other by a suitable interval (e.g., a certain or predetermined interval) in the x direction as illustrated in the portion B of FIG. 31. In an embodiment, the driving voltage line PL may be separated between the second circuit area PCA2 and the third circuit area PCA3, such that the portion B may be located between the second circuit area PCA2 and the third circuit area PCA3. Each sub-line of the driving voltage line PL may include the main line PLm extending in the x direction, and a protrusion PLc protruding in the −y direction from the main line PLm. The protrusion PLc may be located in each circuit area. The plurality of sub-lines may correspond to the plurality of conductive electrodes DCE described above with reference to FIGS. 5A and 5B. The first electrode layer 220 may be provided in an island shape.

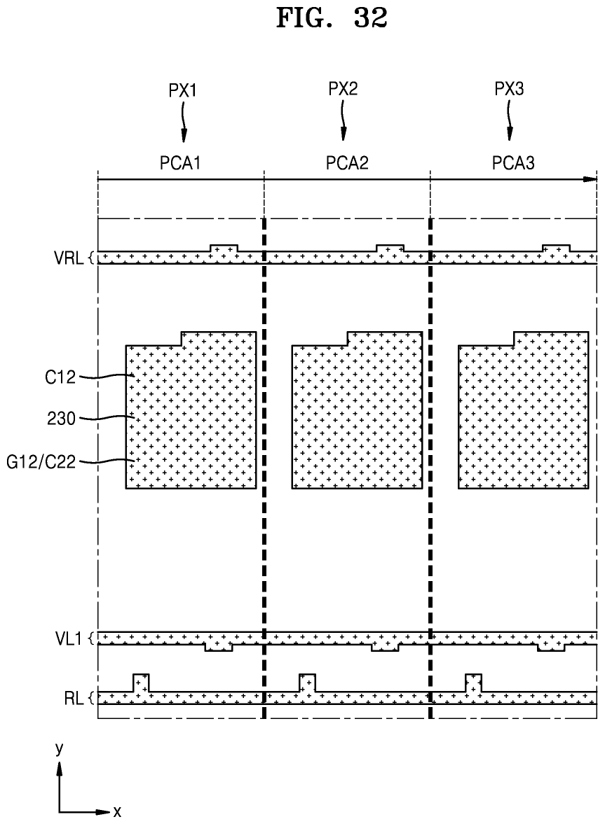

The third insulating layer 113 may be located on the second insulating layer 112 to cover the second conductive layer, and the third conductive layer may be located on the third insulating layer 113. As shown in FIG. 32, the third conductive layer may include the second electrode layer 230, the reference voltage line VRL, and the first initialization voltage line VL1. The third conductive layer may further include the repair line RL.

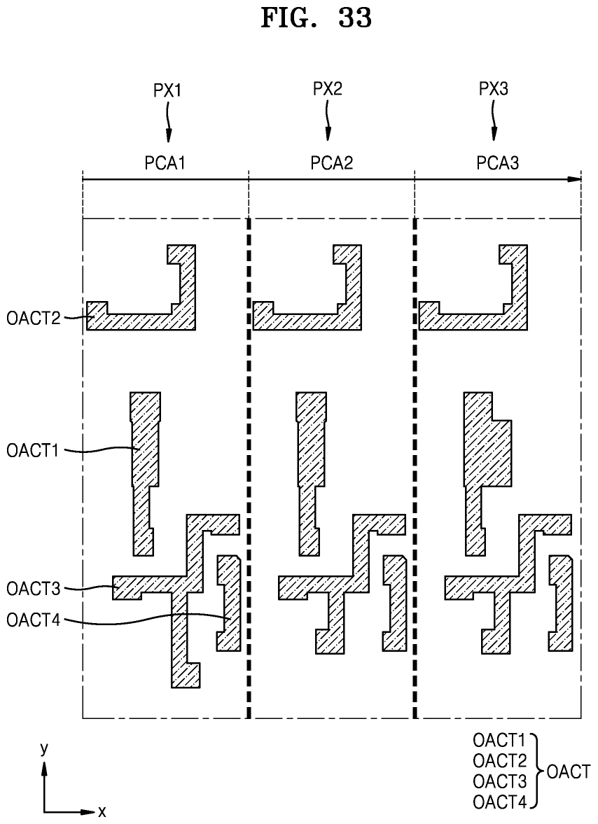

The fourth insulating layer 114 may be located on the third insulating layer 113 to cover the third conductive layer, and the semiconductor layer OACT including an oxide semiconductor may be located on the fourth insulating layer 114 as shown in FIG. 33. The semiconductor layer OACT may include the first semiconductor layer OACT1, the second semiconductor layer OACT2, the third semiconductor layer OACT3, and the fourth semiconductor layer OACT4.

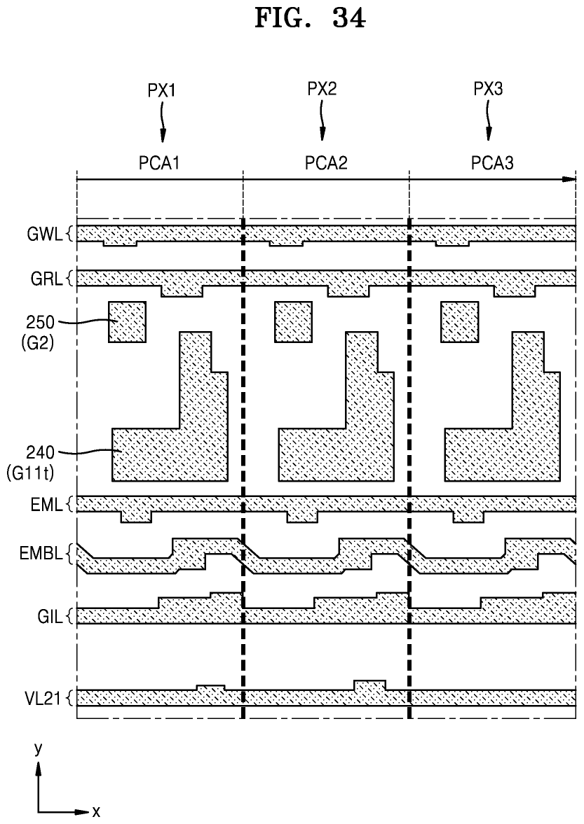

The fifth insulating layer 115 may be located on the fourth insulating layer 114 to cover the semiconductor layer OACT, and the fourth conductive layer may be located on the fifth insulating layer 115. As shown in FIGS. 34 and 16, the fourth conductive layer may include the third electrode layer 240, the fourth electrode layer 250, the first gate line GWL, the second gate line GIL, the third gate line GRL, the fourth gate line EML, the fifth gate line EMBL, and the 2-1^{th} initialization voltage line VL21. Some of the third electrode layer 240, the fourth electrode layer 250, the first gate line GWL, the second gate line GIL, the third gate line GRL, the fourth gate line EML, and the fifth gate line EMBL may include the gate electrodes G1 to G7 of the first to seventh transistors T1 to T7.

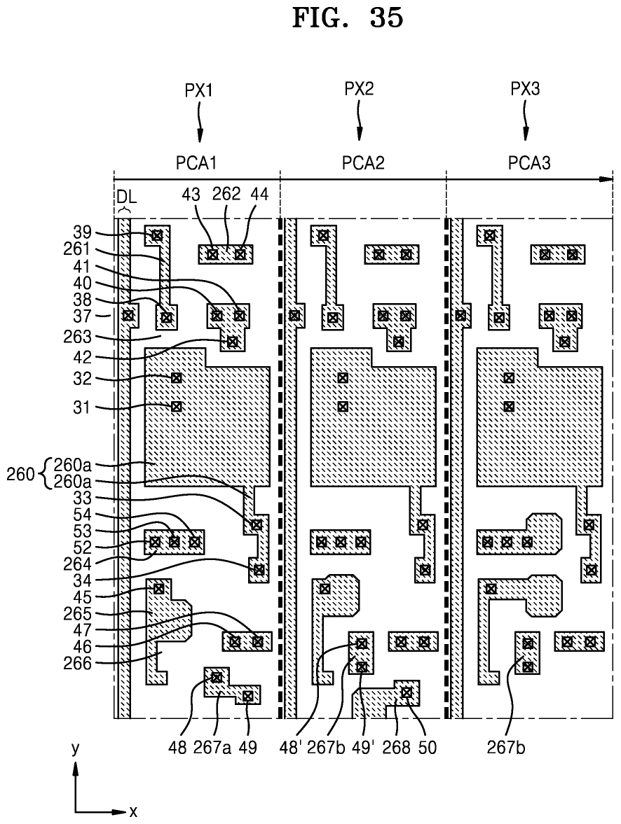

The sixth insulating layer 116 may be located on the fifth insulating layer 115 to cover the fourth conductive layer, and the fifth conductive layer may be located on the sixth insulating layer 116. As shown in FIG. 35, the fifth conductive layer may include the data line DL and the connection electrodes 260, 261, 262, 263, 264, 265, 266, 267a, 267b, and 268.

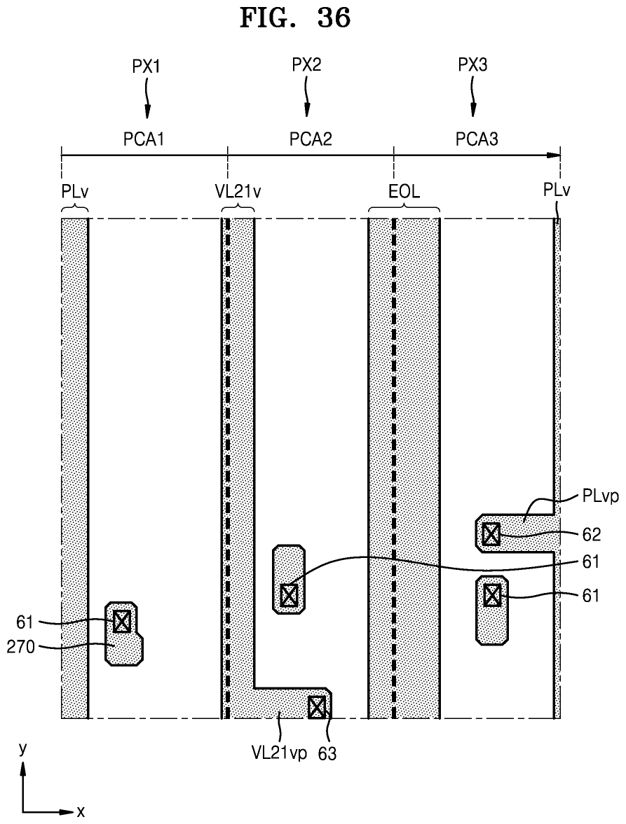

The seventh insulating layer 117 may be located on the sixth insulating layer 116 to cover the fifth conductive layer, and the sixth conductive layer may be located on the seventh insulating layer 117. As shown in FIG. 36, the sixth conductive layer may include a plurality of vertical conductive lines and the connection electrode 270. The plurality of vertical conductive lines may include the vertical driving voltage line PLv, the vertical initialization voltage lines, the common voltage line EOL, and the vertical reference voltage line VRLv. The vertical initialization voltage lines may include the first vertical initialization voltage line VL1v, the 2-1^{th} vertical initialization voltage line VL21v, and the 2-2^{th} vertical initialization voltage line VL22v. FIG. 36 illustrates the vertical driving voltage line PLv, the 2-1^{th} vertical initialization voltage line VL21v, and the common voltage line EOL.

The eighth insulating layer 118 may be located on the seventh insulating layer 117 to cover the sixth conductive layer, and the organic light-emitting diode OLED may be located as the display element on the eighth insulating layer 118.

As shown in FIGS. 37 and 38, the connection electrode 264 may be electrically connected to the protrusion CPp of the semiconductor pattern CP through a contact hole 52 passing through (e.g., penetrating) the second insulating layer 112, the third insulating layer 113, the fourth insulating layer 114, the fifth insulating layer 115, and the sixth insulating layer 116. The connection electrode 264 may be electrically connected to the drain region D5 of the fifth transistor T5, which is a part of the first semiconductor layer OACT1, through a contact hole 53 passing through (e.g., penetrating) the fifth insulating layer 115 and the sixth insulating layer 116. The connection electrode 264 may be electrically connected to the protrusion PLc of the driving voltage line PL through a contact hole 54 passing through (e.g., penetrating) the third insulating layer 113, the fourth insulating layer 114, the fifth insulating layer 115, and the sixth insulating layer 116. The protrusion PLvp of the vertical driving voltage line PLv may be electrically connected to the connection electrode 264 of the third circuit area PCA3 through the contact hole 62 passing through (e.g., penetrating) the seventh insulating layer 117. As shown in FIG. 27, around a pixel of a first column and a pixel of a last column located at an edge of the display area DA, an end of the semiconductor pattern CP and the protrusion PLvp of the vertical driving voltage line PLv may be electrically connected to each other. Accordingly, the semiconductor pattern CP and the plurality of sub-lines of the driving voltage line PL may receive the driving voltage ELVDD.

In an embodiment, the semiconductor pattern CP and the sub-line of the driving voltage line PL may correspond to a semiconductor layer (e.g., the semiconductor pattern CP) and a gate electrode (e.g., the conductive electrode DCE), respectively, of each of a plurality of serially connected silicon thin-film transistors TRs provided in each row as described above with reference to FIGS. 5A through 5C. The vertical driving voltage line PLv may correspond to the signal line SCL for receiving the driving voltage ELVDD as described above with reference to FIGS. 5A through 5C. The portion B between the sub-lines of the driving voltage line PL of FIG. 37 may correspond to the node N as described above with reference to FIGS. 5B and 5C.

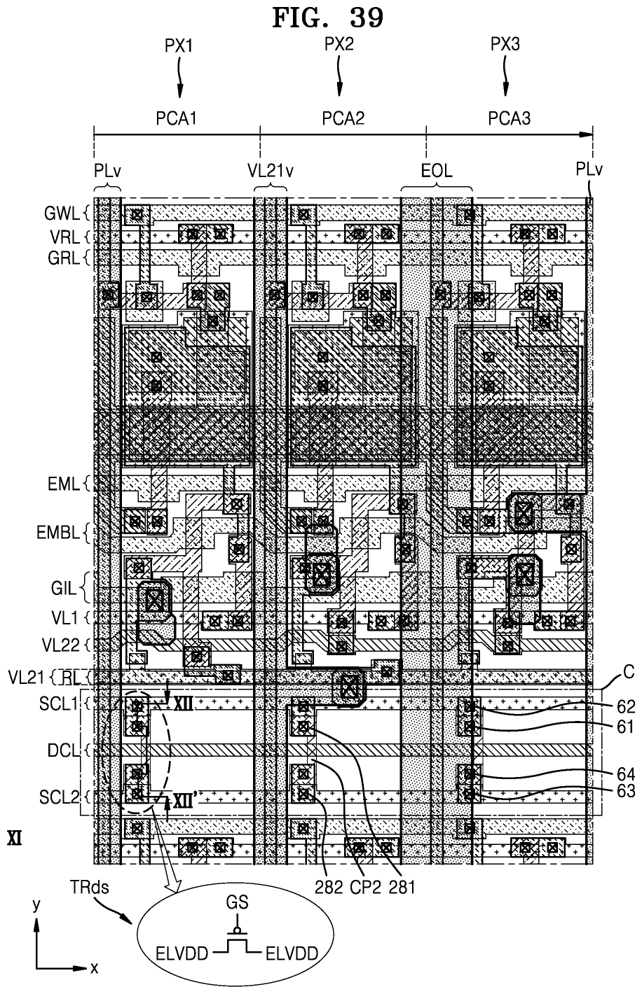

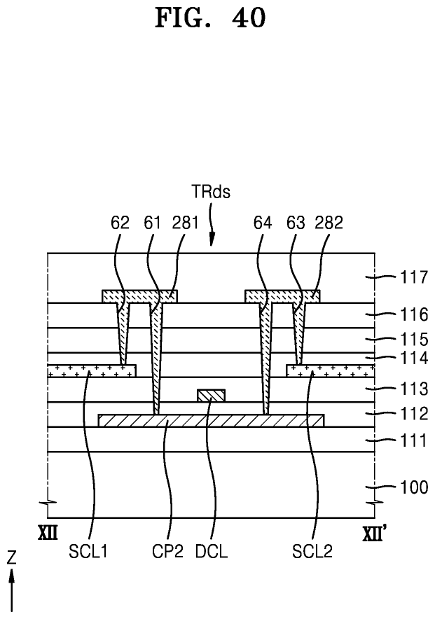

FIG. 39 is a view schematically illustrating transistors and capacitors of the pixel of FIG. 9, according to an embodiment. FIG. 40 is a cross-sectional view taken along the line XII-XII′ of FIG. 39.

In FIG. 39, the same or substantially the same elements as those described above with reference to FIGS. 10 through 25 are denoted by the same reference numerals, and thus, redundant description thereof may not be repeated. In FIG. 39, the reference numerals of some of the same or substantially the same elements as those described above with reference to FIGS. 10 through 25 may be omitted. The elements of the display apparatus of FIG. 39 are the same or substantially the same as (or similar to) those of the display apparatus described above with reference to FIG. 20, except that the first conductive layer 210 is omitted and the elements in the portion C are added. As such, the differences from the embodiments described above with reference to FIGS. 10 through 25 will be mainly described hereinafter.

In an embodiment, a second semiconductor pattern CP2 that is an additional semiconductor pattern may be further provided between adjacent rows of the display area DA. For example, as shown in FIG. 39, the second semiconductor pattern CP2 may be located in the portion C between the 2-1^{th} initialization voltage line VL21 of an arbitrary row and the first gate line GWL of a next row.

In the portion C, a plurality of second semiconductor patterns CP2, a pair of first and second signal lines SCL1 and SCL2, and the conductive layer DCL may be located.

The plurality of second semiconductor patterns CP2 may be spaced apart from each other in the x direction on the substrate 100. The conductive layer DCL extending in the x direction to cross the plurality of second semiconductor patterns CP2 may be located on the second insulating layer 112. The conductive layer DCL may be located over the plurality of second semiconductor patterns CP2 to overlap with the second semiconductor patterns CP2. The pair of first and second signal lines SCL1 and SCL2 may extend in the x direction, and may be located on the third insulating layer 113. The first signal line SCL1 may overlap with ends of the plurality of second semiconductor patterns CP2. The second signal line SCL2 may overlap with the other ends of the plurality of second semiconductor patterns CP2. Connection electrodes 281 and 282 may be located on the sixth insulating layer 116.

As shown in FIG. 40, the connection electrode 281 may be electrically connected to an end of the second semiconductor pattern CP2 through the contact hole 61 passing through (e.g., penetrating) the second insulating layer 112, the third insulating layer 113, the fourth insulating layer 114, the fifth insulating layer 115, and the sixth insulating layer 116. The connection electrode 281 may be electrically connected to the first signal line SCL1 through a contact hole 62 passing through (e.g., penetrating) the fourth insulating layer 114, the fifth insulating layer 115, and the sixth insulating layer 116.

The connection electrode 282 may be electrically connected to the other end of the second semiconductor pattern CP2 through a contact hole 64 passing through (e.g., penetrating) the second insulating layer 112, the third insulating layer 113, the fourth insulating layer 114, the fifth insulating layer 115, and the sixth insulating layer 116. The connection electrode 282 may be electrically connected to the second signal line SCL2 through a contact hole 63 passing through (e.g., penetrating) the fourth insulating layer 114, the fifth insulating layer 115, and the sixth insulating layer 116.

The second semiconductor pattern CP2 may be concurrently or substantially simultaneously formed of the same material as that of the semiconductor pattern CP when the semiconductor pattern CP is formed in a circuit area. The conductive layer DCL may be concurrently or substantially simultaneously formed of the same material as that of the second conductive layer when the second conductive layer is formed in the circuit area. The first signal line SCL1 and the second signal line SCL2 may be concurrently or substantially simultaneously formed of the same material as that of the third conductive layer when the third conductive layer is formed in the circuit area. The connection electrodes 281 and 282 may be concurrently or substantially simultaneously formed of the same material as that of the fifth conductive layer when the fifth conductive layer is formed in the circuit area.

Both ends (e.g., opposite ends) of the conductive layer DCL may be connected to the first gate driving circuit DRV1 and the second gate driving circuit DRV2 to receive the gate signal GS from the first gate driving circuit DRV1 and the second gate driving circuit DRV2. The gate signal GS may be the same or substantially the same as or different from the gate signals applied to the pixel circuit.

The first signal line SCL1 and the second signal line SCL2 may be electrically connected to the vertical driving voltage line PLv at an edge of the display area DA, or may be electrically connected to the driving voltage supply line 11 of the peripheral area PA. Accordingly, the second semiconductor patterns CP2 may receive the driving voltage ELVDD.

The second semiconductor pattern CP2 and the conductive layer DCL may correspond to a semiconductor layer (e.g., the semiconductor pattern CP) and a gate electrode (e.g., conductive layer DCL), respectively, of each of a plurality of parallel-connected silicon thin-film transistors TRds provided in each row as described above with reference to FIGS. 7A through 7C. The vertical driving voltage line PLv may correspond to the signal line SCL for receiving the driving voltage ELVDD as described above with reference to FIGS. 7A through 7C.

In an embodiment, the display apparatus 1 may include the semiconductor pattern CP that is an element of a non-operating silicon thin-film transistor TRs located in a circuit area and the second semiconductor pattern CP2 that is an element of an operating silicon thin-film transistor TRds located around the circuit area, in the display area DA.

Although the display apparatus 1 of FIG. 39 has a structure in which the portion C is added to the pixel circuit of FIG. 25, the present disclosure is not limited thereto. For example, in the display apparatus 1, the portion C may be added to the pixel circuit of FIG. 29, or the semiconductor pattern CP may be omitted in the circuit area, the non-operating silicon thin-film transistor TRs may not be formed, and the operating silicon thin-film transistor TRds including the second semiconductor pattern CP2 as an element may be formed only in the portion C.

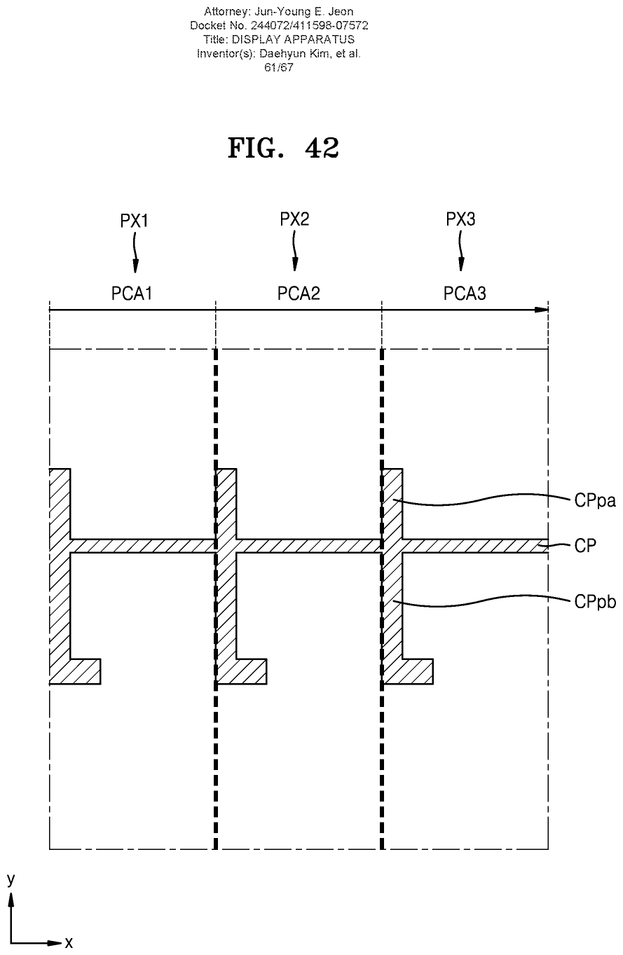

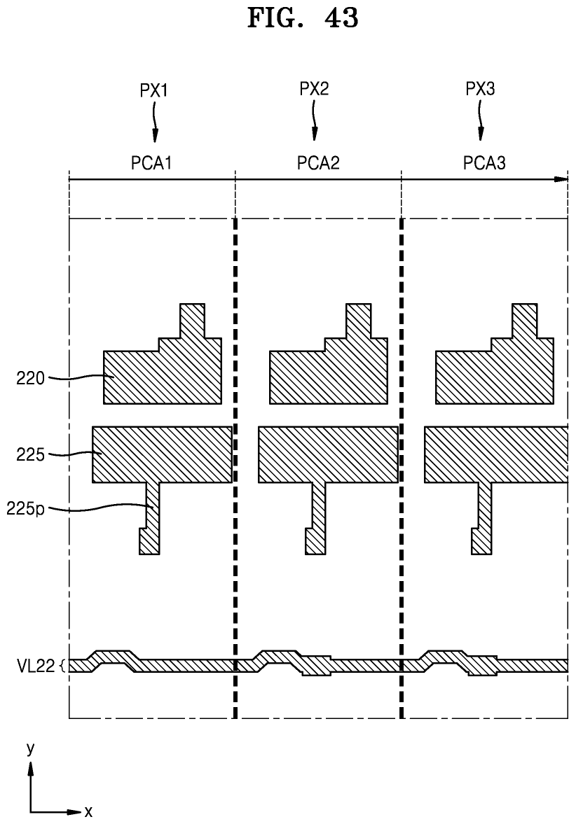

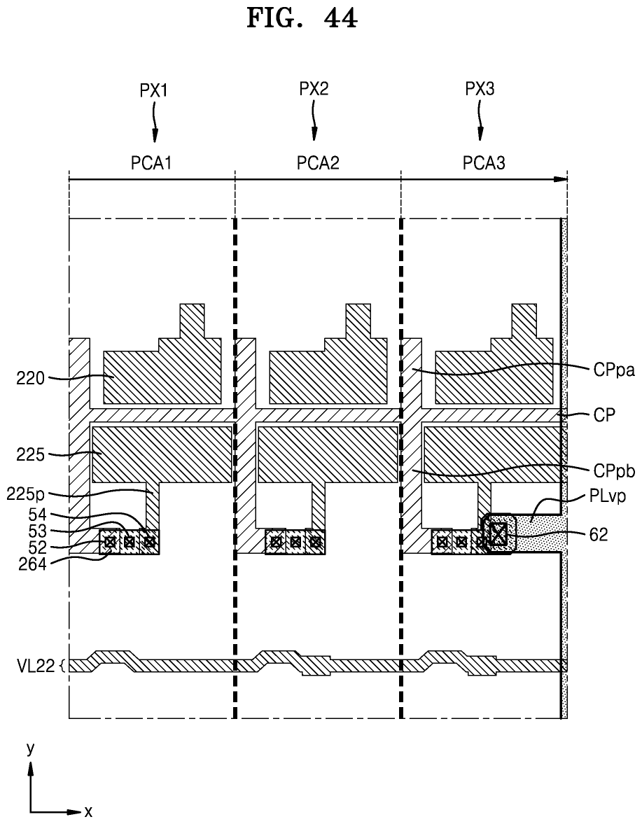

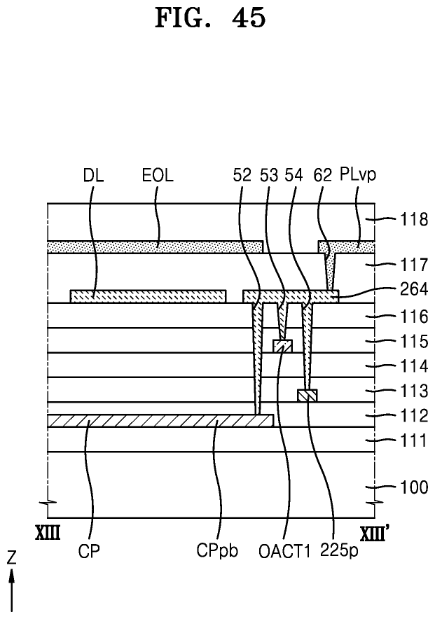

FIG. 41 is a view schematically illustrating transistors and capacitors of the pixel of FIG. 9, according to an embodiment. FIGS. 42 and 43 are views schematically illustrating some elements of a pixel circuit of FIG. 41. FIG. 44 is a layout view illustrating some elements of FIG. 41. FIG. 45 is a cross-sectional view taken along the line XIII-XIII′ of FIG. 41. FIG. 45 is a cross-sectional view illustrating some elements located in the third circuit area PCA3.

In FIG. 41, the same or substantially the same elements as those described above with reference to FIGS. 10 through 25 are denoted by the same reference numerals, and thus, redundant description thereof may not be repeated. In FIG. 41, the reference numerals of some of the same or substantially the same elements as those described above with reference to FIGS. 10 through 25 may be omitted. The elements of the display apparatus of FIG. 41 are the same or substantially the same as (or similar to) the elements of the display apparatus described above with reference to FIG. 20, except that the first conductive layer 210 is omitted and some of the elements are modified. As such, the differences from the embodiments described above with reference to FIGS. 10 through 25 will be mainly described hereinafter.

The first insulating layer 111 may be located on the substrate 100, and the semiconductor pattern CP including a silicon semiconductor may be located on the first insulating layer 111 as shown in FIG. 42. The semiconductor pattern CP may extend in the x direction, and may cross the first circuit area PCA1, the second circuit area PCA2, and the third circuit area PCA3. The semiconductor pattern CP may include a protrusion CPpa protruding in the +y direction and a protrusion CPpb protruding in the −y direction in each circuit area.

The second insulating layer 112 may be located on the first insulating layer 111 to cover the semiconductor pattern CP, and the second conductive layer may be located on the second insulating layer. As shown in FIG. 43, the second conductive layer may include the first electrode layer 220, a fifth electrode layer 225, and the 2-2^{th} initialization voltage line VL22.

Each of the first electrode layer 220 and the fifth electrode layer 225 may be provided in an island shape. The 2-2^{th} initialization voltage line VL22 may extend in the x direction, and may cross the first circuit area PCA1, the second circuit area PCA2, and the third circuit area PCA3. The fifth electrode 225 may include a protrusion 225p protruding in the −y direction from a main body. The protrusion 225p may be located in each circuit area.

The third insulating layer 113 may be located on the second insulating layer 112 to cover the second conductive layer, and the third conductive layer may be located on the third insulating layer 113. As shown in FIG. 13, the third conductive layer may include the second electrode layer 230, the reference voltage line VRL, and the first initialization voltage line VL1. The third conductive layer may further include the repair line RL.

The fourth insulating layer 114 may be located on the third insulating layer 113 to cover the third conductive layer, and the semiconductor layer OACT including an oxide semiconductor may be located on the fourth insulating layer 114 as shown in FIG. 14. The semiconductor layer OACT may include the first semiconductor layer OACT1, the second semiconductor layer OACT2, the third semiconductor layer OACT3, and the fourth semiconductor layer OACT4.

The fifth insulating layer 115 may be located on the fourth insulating layer 114 to cover the semiconductor layer OACT, and the fourth conductive layer may be located on the fifth insulating layer 115. As shown in FIGS. 15 and 16, the fourth conductive layer may include the third electrode layer 240, the fourth electrode layer 250, the first gate line GWL, the second gate line GIL, the third gate line GRL, the fourth gate line EML, the fifth gate line EMBL, and the 2-1^{th} initialization voltage line VL21. Some of the third electrode layer 240, the fourth electrode layer 250, the first gate line GWL, the second gate line GIL, the third gate line GRL, the fourth gate line EML, and the fifth gate line EMBL may include the gate electrodes G1 to G7 of the first to seventh transistors T1 to T7.

The sixth insulating layer 116 may be located on the fifth insulating layer 115 to cover the fourth conductive layer, and the fifth conductive layer may be located on the sixth insulating layer 116. As shown in FIG. 17, the fifth conductive layer may include the data line DL and the connection electrodes 260, 261, 262, 263, 264, 265, 266, 267a, 267b, and 268.

The seventh insulating layer 117 may be located on the sixth insulating layer 116 to cover the fifth conductive layer, and the sixth conductive layer may be located on the seventh insulating layer 117. As shown in FIGS. 18A through 18D, the sixth conductive layer may include a plurality of vertical conductive lines and the connection electrode 270.

The eighth insulating layer 118 may be located on the seventh insulating layer 117 to cover the sixth conductive layer, and the organic light-emitting diode OLED may be located as a display element on the eighth insulating layer 118. The plurality of vertical conductive lines may include the vertical driving voltage line PLv, the vertical initialization voltage lines, the common voltage line EOL, and the vertical reference voltage line VRLv, as shown in FIGS. 18A to 18D. The vertical initialization voltage lines may include the first vertical initialization voltage line VL1v, the 2-1^{th} vertical initialization voltage line VL21v, and the 2-2^{th} vertical initialization voltage line VL22v.

As shown in FIGS. 44 and 45, the connection electrode 264 may be electrically connected to the protrusion CPpb of the semiconductor pattern CP through the contact hole 52 passing through (e.g., penetrating) the second insulating layer 112, the third insulating layer 113, the fourth insulating layer 114, the fifth insulating layer 115, and the sixth insulating layer 116. The connection electrode 264 may be electrically connected to the drain region D5 of the fifth transistor T5, which is a part of the first semiconductor layer OACT1, through the contact hole 53 passing through (e.g., penetrating) the fifth insulating layer 115 and the sixth insulating layer 116. The connection electrode 264 may be electrically connected to the protrusion 225p of the fifth electrode layer 225 through the contact hole 54 passing through (e.g., penetrating) the third insulating layer 113, the fourth insulating layer 114, the fifth insulating layer 115, and the sixth insulating layer 116. The protrusion PLvp of the vertical driving voltage line PLv may be electrically connected to the connection electrode 264 of the third circuit area PCA3 through the contact hole 62 passing through (e.g., penetrating) the seventh insulating layer 117.

As shown in FIGS. 21 and 27, around a pixel of a first column and a pixel of a last column located at an edge of the display area DA, an end of the semiconductor pattern CP and the protrusion PLvp of the vertical driving voltage line PLv may be electrically connected to each other. Accordingly, the semiconductor pattern CP may function has a horizontal wiring having a mesh structure that supplies the driving voltage ELVDD in the display area DA along with the vertical driving voltage line PLv.

In an embodiment, the semiconductor pattern CP is implemented as a constant voltage line that supplies the driving voltage ELVDD to the pixel circuit PCa in the display area DA.

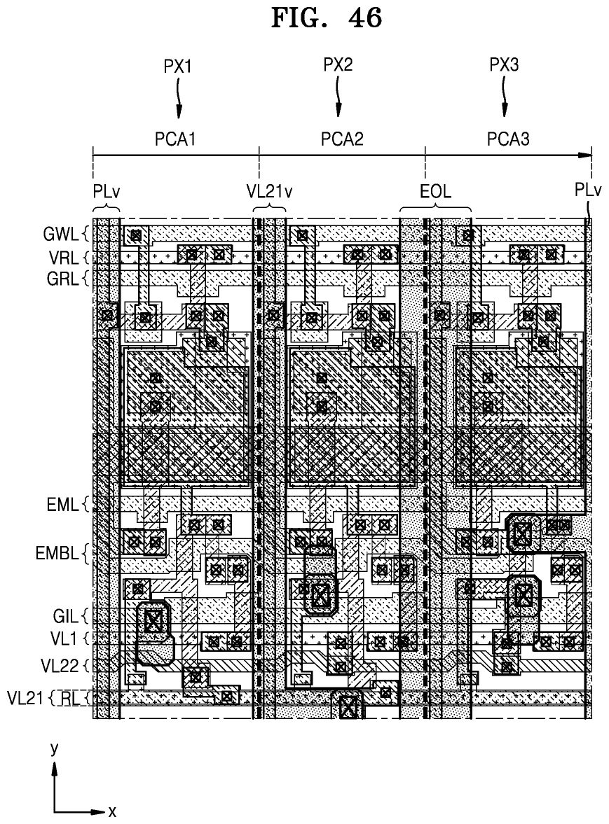

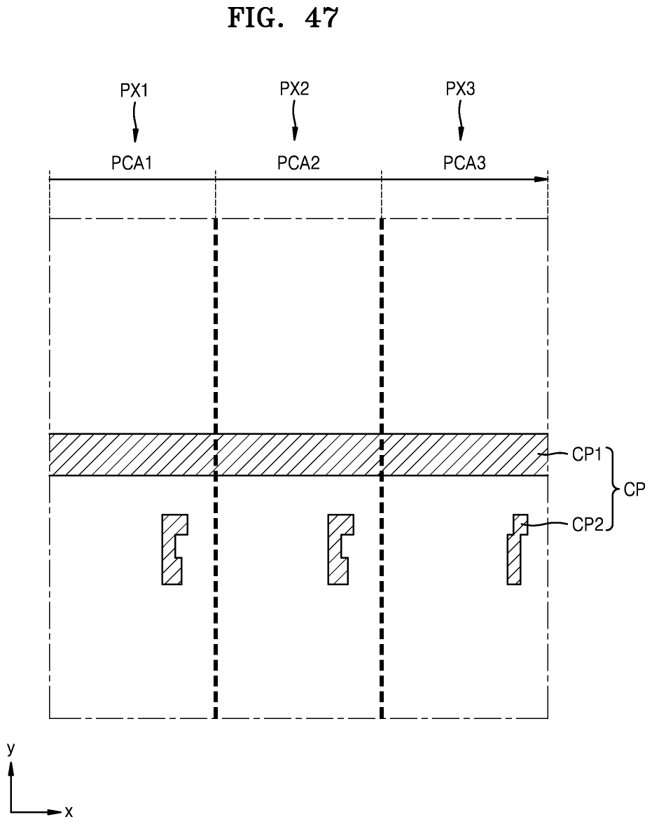

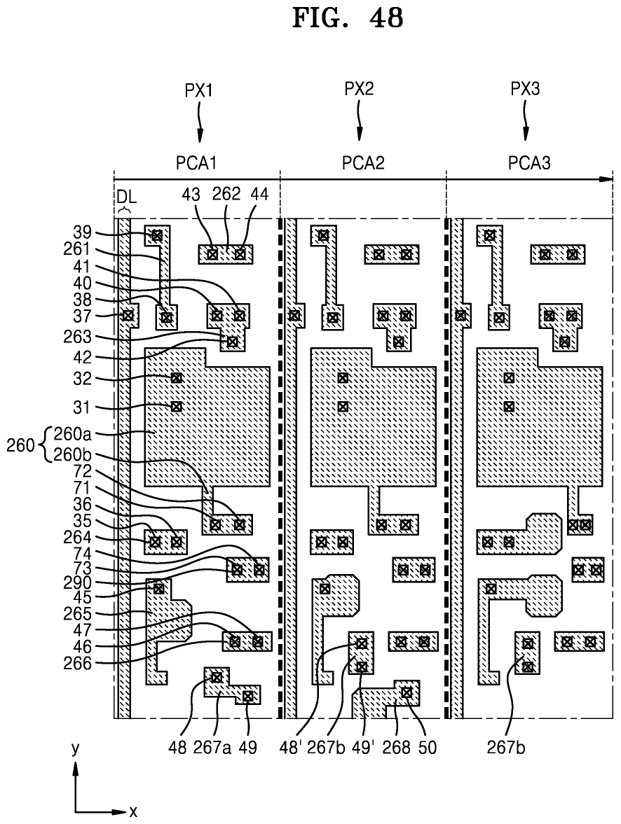

FIG. 46 is a view schematically illustrating transistors and capacitors of the pixel of FIG. 9, according to an embodiment. FIGS. 47 and 48 are views schematically illustrating some elements of a pixel circuit of FIG. 46.

In FIG. 46, the same or substantially the same elements as those described above with reference to FIGS. 10 through 25 are denoted by the same reference numerals, and thus, redundant description thereof may not be repeated. In FIG. 46, the reference numerals of some of the same or substantially the same elements as those described above with reference to FIGS. 10 through 25 may be omitted. The elements of the display apparatus of FIG. 46 may be the same or substantially the same as (or similar to) the elements of the display apparatus described above with reference to FIG. 20, except that the first conductive layer 210 is omitted and some of the elements are modified. As such, the differences from the embodiments described above with reference to FIGS. 10 through 25 will be mainly described hereinafter.

The first insulating layer 111 may be located on the substrate 100, and the semiconductor pattern CP including a silicon semiconductor may be located on the first insulating layer 111 as shown in FIG. 47. The semiconductor pattern CP may include a first semiconductor pattern CP1 and a second semiconductor pattern CP2. The first semiconductor pattern CP1 may extend in the x direction, and may cross the first circuit area PCA1, the second circuit area PCA2, and the third circuit area PCA3. The second semiconductor pattern CP2 may be provided in an island shape in each circuit area.

The second insulating layer 112 may be located on the first insulating layer 111 to cover the semiconductor pattern CP, and the second conductive layer may be located on the second insulating layer 112. As shown in FIG. 12, the second conductive layer may include the first electrode layer 220, the driving voltage line PL, and the 2-2^{th} initialization voltage line VL22.

The third insulating layer 113 may be located on the second insulating layer 112 to cover the second conductive layer, and the third conductive layer may be located on the third insulating layer 113. As shown in FIG. 13, the third conductive layer may include the second electrode layer 230, the reference voltage line VRL, and the first initialization voltage line VL1. The third conductive layer may further include the repair line RL.

The fourth insulating layer 114 may be located on the third insulating layer 113 to cover the third conductive layer, and the semiconductor layer OACT including an oxide semiconductor may be located on the fourth insulating layer 114 as shown in FIG. 14.

The fifth insulating layer 115 may be located on the fourth insulating layer 114 to cover the semiconductor layer OACT, and the fourth conductive layer may be located on the fifth insulating layer 115. As shown in FIGS. 15 and 16, the fourth conductive layer may include the third electrode layer 240, the fourth electrode layer 250, the first gate line GWL, the second gate line GIL, the third gate line GRL, the fourth gate line EML, the fifth gate line EMBL, and the 2-1^{th} initialization voltage line VL21. Some of the third electrode layer 240, the fourth electrode layer 250, the first gate line GWL, the second gate line GIL, the third gate line GRL, the fourth gate line EML, and the fifth gate line EMBL may include the gate electrodes G1 to G7 of the first to seventh transistors T1 to T7.

The sixth insulating layer 116 may be located on the fifth insulating layer 115 to cover the fourth conductive layer, and the fifth conductive layer may be located on the sixth insulating layer 116. As shown in FIG. 48, the fifth conductive layer may include the data line DL and the connection electrodes 260, 261, 262, 263, 264, 265, 266, 267a, 267b, 268, and 290.

The first area 260a of the connection electrode 260 may be electrically connected to the source region S1 of the first transistor T1 through the contact hole 31 passing through (e.g., penetrating) the fifth insulating layer 115 and the sixth insulating layer 116. The first area 260a of the connection electrode 260 may be electrically connected to the second electrode layer 230 through the contact hole 32 passing through (e.g., penetrating) the fourth insulating layer 114, the fifth insulating layer 115, and the sixth insulating layer 116. The second area 260b of the connection electrode 260 may be electrically connected to the drain region D6 of the sixth transistor T6 through a contact hole 71 passing through (e.g., penetrating) the fifth insulating layer 115 and the sixth insulating layer 116. The second region 260b of the connection electrode 260 may be electrically connected to an end of the second semiconductor pattern CP2 through a contact hole 72 passing through (e.g., penetrating) the second insulating layer 112, the third insulating layer 113, the fourth insulating layer 114, the fifth insulating layer 115, and the sixth insulating layer 116.

The connection electrode 290 may be electrically connected to the drain region D4 of the fourth transistor T4 through a contact hole 74 passing through (e.g., penetrating) the fifth insulating layer 115 and the sixth insulating layer 116. The connection electrode 290 may be electrically connected to the other end of the second semiconductor pattern CP2 through a contact hole 73 passing through (e.g., penetrating) the second insulating layer 112, the third insulating layer 113, the fourth insulating layer 114, the fifth insulating layer 115, and the sixth insulating layer 116.

The seventh insulating layer 117 may be located on the sixth insulating layer 116 to cover the fifth conductive layer, and the sixth conductive layer may be located on the seventh insulating layer 117. As shown in FIGS. 18A to 18D, the sixth conductive layer may include a plurality of vertical conductive lines and the connection electrode 270.

The eighth insulating layer 118 may be located on the seventh insulating layer 117 to cover the sixth conductive layer, and the organic light-emitting diode OLED may be located as the display element on the eight insulating layer 118.

In an embodiment, the display apparatus 1 may include the first semiconductor pattern CP1 that is an element of a non-operating silicon thin-film transistor TRs located in a circuit area and the second semiconductor pattern CP2 that is a connection electrode for connecting nodes in the pixel circuit PCa, in the display area DA.

Although the display apparatus 1 of FIG. 46 has a structure in which the second semiconductor pattern CP2 is added to the pixel circuit of FIG. 26, the present disclosure is not limited thereto. For example, in the display apparatus 1, the second semiconductor pattern CP2 may be added to the pixel circuit described above with reference to FIG. 20 or FIG. 29, or the first semiconductor pattern CP1 may be omitted in the circuit area, the non-operating silicon thin-film transistor TRs may not be formed, and only the second semiconductor pattern CP2 may be included.

According to one or more embodiments of the present disclosure described above, a display apparatus having improved display quality may be provided. However, the present disclosure is not limited thereto.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display apparatus comprising a display area and a peripheral area, the display apparatus comprising:
a first thin-film transistor in the peripheral area, and comprising a silicon semiconductor layer;
a second thin-film transistor in the display area, and comprising an oxide semiconductor layer over the silicon semiconductor layer; and
a semiconductor pattern in the display area at the same layer as that of the silicon semiconductor layer of the first thin-film transistor.

2. The display apparatus of claim 1, wherein the semiconductor pattern comprises a silicon semiconductor.

3. The display apparatus of claim 2, wherein the semiconductor pattern is configured to be in a floating state.

4. The display apparatus of claim 1, further comprising:
a conductive layer overlapping with the semiconductor pattern; and
signal lines electrically connected to opposite ends of the semiconductor pattern not overlapping with the conductive layer,
wherein the signal lines are electrically connected to the conductive layer.

5. The display apparatus of claim 4, wherein the conductive layer is at the same layer as that of a gate electrode of the first thin-film transistor.

6. The display apparatus of claim 4, wherein the oxide semiconductor layer of the second thin-film transistor overlaps with the semiconductor pattern.

7. The display apparatus of claim 1, further comprising:
a plurality of conductive electrodes overlapping with the semiconductor pattern; and
signal lines electrically connected to portions of the semiconductor pattern between adjacent conductive electrodes from among the plurality of conductive electrodes,
wherein the signal lines are electrically connected to the plurality of conductive electrodes.

8. The display apparatus of claim 7, wherein the plurality of conductive electrodes are at the same layer as that of a gate electrode of the first thin-film transistor.

9. The display apparatus of claim 7, wherein the oxide semiconductor layer of the second thin-film transistor overlaps with the semiconductor pattern.

10. The display apparatus of claim 1, further comprising:
an upper conductive layer overlapping with the semiconductor pattern;
a lower conductive layer overlapping with the semiconductor pattern; and
signal lines electrically connected to opposite ends of the semiconductor pattern not overlapping with the upper conductive layer,
wherein the signal lines are electrically connected to the upper conductive layer and the lower conductive layer.

11. The display apparatus of claim 10, wherein the upper conductive layer is at the same layer as that of a gate electrode of the first thin-film transistor.

12. The display apparatus of claim 10, wherein the oxide semiconductor layer of the second thin-film transistor overlaps with the semiconductor pattern.

13. The display apparatus of claim 1, wherein the semiconductor pattern comprises a plurality of semiconductor patterns spaced from each other in a row direction, and
wherein the display apparatus further comprises:
a conductive layer overlapping with the plurality of semiconductor patterns to cross the plurality of semiconductor patterns;
a first signal line electrically connected to ends of the plurality of semiconductor patterns; and
a second signal line electrically connected to other ends of the plurality of semiconductor patterns.

14. The display apparatus of claim 13, wherein the first signal line and the second signal line are configured to be applied with a constant voltage signal, and
wherein the conductive layer is configured to be applied with a signal comprising a voltage of a first voltage level and a voltage of a second voltage level lower than the first voltage level.

15. The display apparatus of claim 13, further comprising:
a second semiconductor pattern at the same layer as that of the plurality of semiconductor patterns, and extending in the row direction;
a second conductive layer overlapping with the second semiconductor pattern; and
third signal lines electrically connected to opposite ends of the second semiconductor pattern not overlapping with the second conductive layer,
wherein the third signal lines are configured to be applied with the same voltage as that supplied to the first signal line and the second signal line.

16. The display apparatus of claim 1, further comprising:
a conductive layer overlapping with the semiconductor pattern; and
a signal line electrically connected to the conductive layer.

17. The display apparatus of claim 1, wherein the semiconductor pattern is electrically connected to a conductive line configured to supply a constant voltage.

18. The display apparatus of claim 1, further comprising a third thin-film transistor in the display area, and comprising an oxide semiconductor layer over the silicon semiconductor layer,
wherein the semiconductor pattern is configured to electrically connect the oxide semiconductor layer of the second thin-film transistor to the oxide semiconductor layer of the third thin-film transistor.

19. A display apparatus comprising a display area and a peripheral area, the display apparatus comprising:
a semiconductor pattern in the display area;
a conductive layer on the semiconductor pattern, and overlapping with the semiconductor pattern;
a first electrode layer on the conductive layer, and overlapping with the conductive layer;
an oxide semiconductor layer on the first electrode layer;
a second electrode layer on the oxide semiconductor layer; and
a third electrode layer on the second electrode layer, and overlapping with the second electrode layer.

20. The display apparatus of claim 19, wherein the semiconductor pattern comprises a silicon semiconductor.

21. The display apparatus of claim 19, further comprising a lower conductive layer in the display area between a substrate and the semiconductor pattern,
wherein the semiconductor pattern overlaps with the lower conductive layer.

22. The display apparatus of claim 19, further comprising:
a silicon semiconductor layer in the peripheral area; and
a fourth electrode layer on the silicon semiconductor layer, and overlapping with the silicon semiconductor layer,
wherein the silicon semiconductor layer is at the same layer as that of the semiconductor pattern, and
wherein the fourth electrode layer is at the same layer as that of the conductive layer.
